(19) United States
(12) Patent Application Publication
(10) Pub. No.: US 2025/0108396 A1
(43) Pub. Date: Apr. 3, 2025

(54) Spray gun and control method of spray gun

(71) Applicant: Greenworks (Jiangsu) Co., Ltd., Changzhou (CN)

(72) Inventors: Xiuzhen WU, Changzhou (CN); Hailong HUANG, Changzhou (CN); Yingtang LING, Changzhou (CN); Yuanjian CUI, Changzhou (CN); Chunlin ZHAO, Changzhou (CN); Kaihong TANG, Changzhou (CN)

(73) Assignee: Greenworks (Jiangsu) Co., Ltd., Changzhou (CN)

(21) Appl. No.: 18/977,891

(22) Filed: Dec. 11, 2024

Related U.S. Application Data
(63) Continuation of application No. PCT/CN2023/087531, filed on Apr. 11, 2023.

(30) Foreign Application Priority Data
Jun. 22, 2022 (CN) 202210714579.2
Jun. 22, 2022 (CN) 202210727841.7
Jun. 22, 2022 (CN) 202221576038.X
Jun. 22, 2022 (CN) 202221580675.4
Jun. 22, 2022 (CN) 202221588154.3
Jun. 22, 2022 (CN) 202221600369.2
Jun. 22, 2022 (CN) 202221607180.6

(51) Int. Cl. B05B 12/00; B05B 9/08; B08B 3/02; B08B 13/00

(52) U.S. Cl. CPC B05B 12/004; B05B 9/0861; B08B 3/026; B08B 13/00; B08B 2203/0211; B08B 2203/0217; B08B 2203/0223; B08B 2203/0247

(57) ABSTRACT

A spray gun includes a gun body, a flow passage, a fluid driving element, a control module, a switch assembly and a battery pack. The control module is configured to obtain power information of the battery pack and/or working state information of the fluid driving element, and display the power information of the battery pack and/or the working state information of the fluid driving element through a visual interface module.

### CROSS REFERENCE TO RELATED APPLICATION

The present application is a continuation Application of PCT application No. PCT/CN2023/087531 filed on Apr. 11, 2023, which claims the benefit of CN202221607180.6 filed on Jun. 22, 2022, CN202221580675.4 filed on Jun. 22, 2022, CN202221588154.3 filed on Jun. 22, 2022, CN202221576038.X filed on Jun. 22, 2022, CN202210714579.2 filed on Jun. 22, 2022, CN202210727841.7 filed on Jun. 22, 2022 and CN202221600369.2 filed on Jun. 22, 2022. All the above are hereby incorporated by reference for all purposes.

### TECHNICAL FIELD

The disclosure belongs to a technical field of cleaning tools, and in particular relates to a spray gun and a control method of the spray gun.

### BACKGROUND

Pressure washer gun is used to clean vehicles, boats, buildings, porches, decks, bicycles, and outdoor furniture. As one of the various accessories of the high-pressure cleaning machine, the multi-in-one spray nozzle (spray wand) integrates multiple spray nozzles and realizes the integration of multiple water shapes in one, allowing customers to flexibly switch cleaning modes according to the needs of different cleaning conditions.

### SUMMARY

The disclosure provides a spray gun that can select pressure according to actual needs, thereby extending a battery life.

One or more embodiments of the disclosure provide the spray gun, the spray gun includes a gun body, a flow passage, a fluid driving element, a control module, a visual interface module, a switch assembly and a battery pack.

The flow passage is formed in the gun body, a first end of the flow passage passes through the gun body to form a water inlet of the spray gun on an outside of the gun body, and a second end of the flow passage is communicated with a spraying head.

The fluid driving element is installed in the gun body and configured to drive fluid in the flow passage.

The control module is electrically coupled to the fluid driving element.

The visual interface module is installed on the gun body, exposed on a surface of the gun body, and electrically coupled to the control module.

The switch assembly is electrically connected with the control module and at least includes an on-off switch and a speed regulation switch.

The battery pack is electrically connected with the control module.

The control module is configured to obtain power information of the battery pack and/or working state information of the fluid driving element, and display the power information of the battery pack and/or the working state information of the fluid driving element through the visual interface module.

In an embodiment of the disclosure, the gun body further includes a gun body assembly, a gun head assembly and a battery pack compartment.

The gun body assembly is enclosed by a housing, formed with a handle part, and the fluid driving element, the control module and the switch assembly are installed on the gun body assembly.

The gun head assembly is detachably installed on a front end of the gun body assembly, and a front end of the gun head assembly is provided with the spraying head.

The battery pack compartment is located at a lower end of the handle part, and the battery pack is installed in the battery pack compartment.

In an embodiment of the disclosure, the visual interface module includes a display screen and/or an atmosphere light, and the display screen is installed at a rear end of the gun body assembly.

In an embodiment of the disclosure, the speed regulation switch is installed in a position touchable by the thumb of a user when the user holds the handle part.

In an embodiment of the disclosure, a clamping ring is provided at the rear end of the gun body assembly, the clamping ring is detachably connected with the gun body assembly, the display screen is accommodated in the clamping ring, a first protruding flange is arranged on an inner wall of the clamping ring, and the first protruding flange abuts against an outer edge of the display screen to limit the display screen within the clamping ring.

In an embodiment of the disclosure, the gun head assembly includes a gun barrel, an outer housing, a spraying head and an auxiliary agent container.

The outer housing is configured to cover an outside of the gun barrel.

The spraying head is connected with a front end of the gun barrel.

The auxiliary agent container is installed on the outer housing and communicated with the gun barrel through a pipeline.

In an embodiment of the disclosure, a quick-connector is arranged between the gun barrel and the flow passage inside the gun body assembly, a floating ring is arranged on the gun body assembly or the gun head assembly, the floating ring is movably connected with the gun body assembly or the gun head assembly along an axis direction of the gun barrel, an elastic element is arranged between the floating ring and the gun body assembly or the gun head assembly, when the quick-connectors are connected with each other, and the elastic element is compressed to cause the floating ring to press against an end face of the gun body assembly or against an end face of the gun head assembly.

In an embodiment of the disclosure, the spraying head is coaxially arranged with the gun barrel, the spraying head includes a fixing component and a spraying head housing, the fixing component is fixedly connected with the gun barrel, a first flow passage coaxially arranged with an axis of the gun barrel and a second flow passage eccentrically arranged relative to the axis of the gun barrel are formed in the fixing component, the spraying head housing is rotatably connected with the fixing component, a plurality of spray nozzles are circumferentially arranged at a front end of the spraying head housing, and when the spraying head housing rotates relative to the fixing component, each of the spray nozzle is capable of being alternately communicated with the second flow passage.

In an embodiment of the disclosure, a right-angle tube is connected with the gun barrel, the right-angle tube passes through the housing and forms an auxiliary agent container connector parallel to the gun barrel on an outside of the outer housing, the auxiliary agent container is connected with the auxiliary agent container connector along a direction parallel to the gun barrel.

In an embodiment of the disclosure, a sliding clamping mechanism is arranged between the outer housing and the auxiliary agent container, the sliding clamping mechanism includes a first connecting part fixed with the outer housing and a second connecting part fixed with the auxiliary agent container.

In an embodiment of the disclosure, a limiting protrusion is arranged on the first connecting part, and a limiting groove matched with the limiting protrusion is arranged on an inner wall of the second connecting part.

In an embodiment of the disclosure, the battery pack compartment includes a body and a compartment cover, and the compartment cover and the body are respectively provided with magnetic units.

Technical effects of one or more exemplary embodiments of the disclosure are that remaining power of the battery pack and a working state of the fluid driving element may be displayed in real time through the visual interface module. A user can reasonably set working power of the spray gun according to the remaining power and only turn on a high-power mode when necessary, for example, to clean stubborn stains. This can reasonably distribute power of the battery pack, improve an endurance of the spray gun, and avoid battery replacement or charging in a middle of a process, and thus improving work efficiency.

The outer housing of one or more exemplary embodiments of the disclosure is not restricted by a pressure-bearing performance requirement and may be made of materials that are beneficial to the appearance, thereby avoiding direct exposure of the gun barrel to the outside, improving an integrity and appearance consistency of a product, allowing a variety of color options, and providing a rich selection space for product industrial design and achieving a flexible and changeable appearance.

The floating ring of one or more exemplary embodiments can compensate for the assembly gap, improve a stability between the gun body assembly and the gun head assembly, and enhance an appearance quality of the spray gun.

One or more exemplary embodiments of the disclosure adopt a magnetic attraction structure to realize a connection between the battery pack compartment and the compartment cover. There will be no problem of a buckle breakage, and assembly and disassembly are very easy.

One or more embodiments of the disclosure further provide a display screen mounting structure for a spray gun that is easy to disassemble.

One or more embodiments of the disclosure provide the display screen mounting structure of the spray gun, and the display screen mounting structure includes a gun body assembly, a clamping ring and a display screen,

The gun body assembly serves as a covering component to cover a surface of the spray gun.

The clamping ring is detachably connected with the gun body assembly.

The display screen is installed on the clamping ring in a manner that a display surface of the display screen is capable of being exposed.

In an embodiment of the disclosure, a first limiting part is arranged on the gun body assembly, a second limiting part is arranged on the clamping ring, the first limiting part and the second limiting part are assembled so that when the clamping ring and the gun body assembly are in a connected state, and the first limiting part and the second limiting part are capable of blocking each other to prevent the clamping ring from separating from the gun body assembly.

In an embodiment of the disclosure, at least one of the first limiting part and the second limiting part is assembled to be capable of deforming or displacing under an action of external force so as to release a mutual blocking state between the first limiting part and the second limiting part.

In an embodiment of the disclosure, the clamping ring is an annular structure, and an annular plug-in part is formed on the gun body assembly, the plug-in part is plugged into an inner wall of the clamping ring.

In an embodiment of the disclosure, the second limiting part includes a second wedge part arranged on the inner wall of the clamping ring, the first limiting part includes a first wedge part arranged on an outer wall of the plug-in part, notches are formed on the plug-in parts on two sides of the first limiting part so that an area where the first limiting part is located forms a cantilever structure

In an embodiment of the disclosure, one of the clamping ring and the plug-in part is provided with a positioning pin, and the other one of the clamping ring and the plug-in part is provided with a positioning groove plug-in fitted with the positioning pin.

In an embodiment of the disclosure, the clamping ring is connected with one end of the gun body assembly that forms a tail part of the spray gun.

In an embodiment of the disclosure, a step part is formed between the plug-in part and the gun body assembly, and a thickness of the step part is consistent with a thickness of the clamping ring, so that when the clamping ring is connected with the gun body assembly, a surface of the clamping ring is flush with a surface of the gun body assembly.

In an embodiment of the disclosure, an end of the clamping ring away from the gun body assembly is provided with a first protruding flange protruding inward, and an edge of the display screen to limit the display screen is blocked by the first protruding flange within the clamping ring.

In an embodiment of the disclosure, a through hole is formed in an area of the gun body assembly connected with the clamping ring, so that a mounting area of the display screen is communicated with an inner area of the gun body assembly.

The technical effects of one or more exemplary embodiments of the disclosure are that the clamping ring is added on an outside of the gun body assembly and connected to the body of the gun body assembly through the buckle, so that the display screen is pressed and installed onto the gun body assembly, thereby reducing a scrap rate of the gun body assembly caused by screen problems, shortening the rework time, and improving the assembly efficiency.

One or more embodiments of the disclosure provide a gun head assembly with a symmetrical overall appearance and convenient for spray nozzle adjustment.

The gun head assembly includes a fixing component and a spraying head housing.

The first flow passage is formed in a center of the fixing component along an axial direction, a second flow passage is formed at a position off the center of the fixing component, the second flow passage is communicated with the first flow passage, the first flow passage passes through a rear end of the fixing component, and the second flow passage passes through a front end of the fixing component.

The spraying head housing is coaxially arranged with the fixing component and the spraying head housing and the fixing component is rotatably connected with each other, the spraying head housing at least coves a front end of the fixing component, a plurality of spray nozzles is arranged on a housing wall of the spraying head housing opposite to the front end of the fixing component, each of the spray nozzle is arranged at intervals along a circumferential direction of the first flow passage, and when the spraying head housing rotates relative to the fixing component, each spray nozzle is alternately communicated with the second flow passage.

In an embodiment of the disclosure, the gun head assembly further includes a floating plate and a first elastic unit

The floating plate is located between the front end of the fixing component and an inner wall of the spraying head housing, the floating plate movably is arranged along an axial direction of the fixing component, and a through hole is arranged on the floating plate at a position corresponding to the second flow passage.

The first elastic unit is configured to enable an elastic force to act forward on the floating plate so as to keep the floating plate in a state of abutting against the inner wall of the spraying head housing.

In an embodiment of the disclosure, a first sealing ring is arranged between each of the spray nozzles and the floating plate.

In an embodiment of the disclosure, a protruding ring protruding toward the second flow passage is arranged at a position on the floating plate corresponding to the through hole, and the protruding ring is inserted into the second flow passage and fits against an inner wall of the second flow passage.

In an embodiment of the disclosure, a sinking groove is arranged at a front end of the second flow passage, the protruding ring is inserted into the sinking groove, a gasket is arranged between the protruding ring and the sinking groove, a second sealing ring is arranged between the protruding ring and the gasket, the first elastic unit is a compression spring, the compression spring is installed in the second flow passage, and a front end of the compression spring abuts against the gasket.

In an embodiment of the disclosure, the spraying head housing further includes a cylindrical part covering a side surface of the fixing component, and a third sealing ring is arranged between an inner wall of the cylindrical part and the side surface of the fixing component.

In an embodiment of the disclosure, an annular groove is arranged on the side surface of the fixing component, a limiting ring is arranged in the annular groove, the limiting ring is rotatably matched with the fixing component relatively, the spraying head housing is relatively fixedly connected with the limiting ring in a detachable manner, a limiting unit is arranged between the limiting ring and the fixing component, and the limiting unit is configured to keep the spraying head housing in a state that any of the spray nozzles on the spraying head housing is communicated with the second flow passage, and to release the spraying head housing when the spraying head housing is subjected to a torque greater than a preset value.

In an embodiment of the disclosure, the limiting unit includes a limiting block movably arranged along a radial direction of the fixing component, at least an outer end of the limiting block has a smooth outer contour, a second elastic unit is arranged between the limiting block and the fixing component, the second elastic unit is configured so that an elastic force acting on the limiting block is capable of driving the limiting block to move outward along the radial direction of the fixing component, a first limiting groove matched with the limiting block is arranged on an inner wall of the limiting ring, there is a plurality of the first limiting grooves, and each of the first limiting grooves is arranged at intervals along a circumferential direction of the limiting ring.

In an embodiment of the disclosure, the limiting ring includes two half rings.

In an embodiment of the disclosure, the cylindrical part is threaded with the limiting ring, a locking block is arranged on the inner wall of the cylindrical part, a locking groove is arranged on an edge of the limiting ring, the locking groove is formed between two cantilevers, a first one of the cantilevers is fixedly connected with the limiting ring, and a second one of the cantilever is elastically connected with the limiting ring, and the second cantilever is configured so that the locking block is capable of pushing the cantilever away to fall into the locking groove during a process of a threaded connection between the cylindrical part and the limiting ring, and the cantilever is capable of preventing the locking block from moving out of the locking groove.

One or more embodiments of the disclosure provide a spraying rod assembly applied to the spray gun. The spraying rod assembly includes a gun barrel, a gun head assembly and an outer housing.

The gun head assembly is located at a front end of the gun barrel, and coaxially arranged with the gun barrel, a plurality of spray nozzles is arranged at a front end of the gun head assembly, the spray nozzles are arranged at intervals along a circumferential direction of the gun head assembly, a flow passage is arranged in the gun head assembly, the flow passage is communicated with the gun barrel, the gun head assembly includes an adjustment device, and the adjustment device is configured to enable each spray nozzle to be alternately communicated with the flow passage.

The outer housing serves as a surface decoration component of the gun barrel, and is detachably installed on an outer side of the gun barrel.

Beneficial effects of one or more exemplary embodiments of the disclosure are that:
an axis of the gun head assembly is arranged colinearly with an axis of the gun barrel, and water flow is guided to a position corresponding to the spray nozzle through a second flow passage, thereby realizing a symmetrical design of the gun head assembly relative to the gun barrel, and meeting different industrial styling requirements, and when switching the spray nozzle, an adjustment device can be rotated along the axis of the gun barrel, which enables an adjustment to be more convenient.

The outer housing of one or more exemplary embodiments of the disclosure is not restricted by the pressure-bearing performance requirement and may be made of materials that are beneficial to the appearance, thereby avoiding direct exposure of the gun barrel to the outside, improving the integrity and appearance consistency of a product, allowing the variety of color options, and providing the rich selection space for product industrial design and achieving the flexible and changeable appearance.

One or more embodiments of the disclosure provide a connecting device. The connecting device includes the first connecting part, the second connecting part, the first limiting part, the second limiting part and the elastic element.

The second connecting part is plug-in fitted with the first connecting part.

The first limiting part is formed on the first connecting part.

The second limiting part is formed on the second connecting part. When the first connecting part and the second connecting part are plugged into a preset position, the second limiting part is capable of forming a limiting match with the first connecting part, to keep the first connecting part and the second connecting part in the preset position; and

The elastic element is configured to apply an elastic force to the first connecting part and the second connecting part so as to cause the first connecting part and the second connecting part to be separated from each other when the first connecting part and the second connecting part are plugged into the preset position.

In an embodiment of the disclosure, the connecting device further includes a floating ring, the floating ring is movably connected with the first connecting part, a moving direction of the floating ring is parallel to a plug-in direction of the first connecting part and the second connecting part, the first connecting part has an annular housing wall, an outer wall of the floating ring is in contact with an inner wall of the annular housing wall, the elastic element acts on the floating ring, when the first connecting part and the second connecting part are plugged into the preset position, and the elastic force of the elastic element is capable of driving an end face of the floating ring to contact an end face of the second connecting part.

In an embodiment of the disclosure, the first connecting part includes the first tube, the second connecting part includes the gun barrel, when the first connecting part and the second connecting part are plugged into the preset position, and the first tube is fluidically communicated with the gun barrel.

In an embodiment of the disclosure, the first limiting part includes a limiting hole with a non-circular cross-section, the second limiting part includes an inserting rod, and a limiting head arranged at an end part of the inserting rod and matched with a contour of a cross-section of the limiting hole, a third notch is arranged on a hole wall of the limiting hole, when the first connecting part and the second connecting part are plugged into the preset position, the limiting head is aligned with the third notch, and at this time, the limiting head is rotated to enable a contour of a cross-section of the limiting head to be misaligned with the contour of the cross-section of the limiting hole, so as to block the limiting head in the third notch.

In an embodiment of the disclosure, the first connecting part includes a casing, a clamping hood and a core body.

The casing is provided with a cylindrical part.

The clamping hood is sleeved on an outer side of the cylindrical part.

The core body is detachably installed in the cylindrical part.

In an embodiment of the disclosure, the first limiting part is formed on the core body.

In an embodiment of the disclosure, the floating ring is located between the core body and the casing and/or the clamping hood.

In an embodiment of the disclosure, a protruding block is arranged on an outer wall of the core body, the elastic element is a compression spring, a first end of the compression spring abuts against the first protruding block, and a second end of the compression spring abuts against the floating ring.

In an embodiment of the disclosure, the second connecting part includes an outer housing covering an outside of the gun barrel, a side wall of the outer housing close to one end of the first connecting part is flush with the outer wall of the floating ring, and when the first connecting part and the second connecting part are plugged into the preset position, the end face of the floating ring contacts an end face of the outer housing.

One or more embodiments of the disclosure further provide the spray gun, and the spray gun includes a gun body assembly and a gun head assembly.

The gun body assembly includes a first connecting part.

The gun head assembly includes a second connecting part.

The gun body assembly is detachably connected with the gun head assembly through the first connecting part and the second connecting part.

The second connecting part is plug-in fitted with the first connecting part.

The first connecting part includes a first limiting part and a first tube.

The second connecting part includes a second limiting part and a gun barrel.

When the first connecting part and the second connecting part are plugged into a preset position, the second limiting part is capable of forming a limiting match with the first connecting part, to keep the first connecting part and the second connecting part in the preset position.

The spray gun further includes an elastic element, the elastic element is configured to apply an elastic force to the first connecting part and the second connecting part so as to cause the first connecting part and the second connecting part to be separated from each other when the first connecting part and the second connecting part are plugged into the preset position.

Beneficial effects of one or more exemplary embodiments of the disclosure are that:
the elastic element causes the first connecting part and the second connecting part to have a tendency to be separated from each other, while the first limiting part and the second limiting part can prevent a separation of the first connecting part and the second connecting part. Therefore, there will always be a certain internal stress between the first connecting part and the second connecting part, and this internal stress may enable the two components fit as closely as possible, reduce the error caused by assembly, and prevent looseness between the gun head assembly and the gun body assembly.

The floating ring of one or more exemplary embodiments can eliminate cracks on a surface of a connecting part between the gun body assembly and the gun head assembly. As a floating part, the floating ring can maintain a fit with the first connecting part and the second connecting part, which is equivalent to filling a gap between the first connecting part and the second connecting part, ensuring that the connecting part has a complete and continuous appearance shape, thereby improving an appearance quality of the product.

One or more embodiments of the disclosure further provide an auxiliary agent container mounting structure for the spray gun which can be installed horizontally and has a simple and efficient assembly process. The auxiliary agent container mounting structure includes a first port, a second port, a first connecting part and a second connecting part.

The first port is formed on an outer side of the gun head assembly of the spray gun, communicated with the flow passage in the gun head assembly, and arranged toward a front end or a rear end of the gun head assembly.

The second port is formed on an outer side of the auxiliary agent container and communicated with a liquid storage space inside the auxiliary agent container.

The first connecting part is formed on an outer wall of the gun head assembly.

The second connecting part is formed on an outer wall of the auxiliary agent container.

The first connecting part and the second connecting part are configured such that when the auxiliary agent container moves along a front-rear direction of the gun head assembly to connect the first port with the second port, the first connecting part and the second connecting part are capable of being clamped with each other to fix the auxiliary agent container to the outer wall of the gun head assembly.

In an embodiment of the disclosure, one of the first connecting part and the second connecting part includes a sliding block, and the other one of the first connecting part and the second connecting part includes a sliding groove, wings are arranged on two sides of the sliding block and protrude perpendicularly to a length direction of the gun head assembly, a strip groove matching the wings is arranged on a side wall of the sliding groove, a first notch is arranged at a notch port of the sliding groove, the first notch penetrates from a notch port of the sliding groove to the strip groove, so as to insert the wing into the strip groove through the first notch.

In an embodiment of the disclosure, a first restrict part is arranged on the wing or the sliding block, a second restrict part is arranged on an inner wall of the sliding groove or the strip groove, one of the first restrict part and the second restrict part is a first protruding part with a smooth surface, the other one of the first restrict part and the second restrict part is a first concave part, when the first port is connected with the second port, the first protruding part is clamped with the first concave part.

In an embodiment of the disclosure, the auxiliary agent container includes a container body and a side cover, a bottle mouth is formed on the container body, the side cover is detachably installed on the bottle mouth, and the second port is located on the side cover.

In an embodiment of the disclosure, a second protruding block is arranged on an outer wall of the bottle mouth, an arc groove matched with the second protruding block is arranged on an inner wall of the side cover, a second notch is arranged at an end part of the side cover, and the second notch penetrates into the arc groove to enable the second protruding block to be inserted into the arc groove through the second notch.

In an embodiment of the disclosure, a second protruding part with a smooth surface is arranged on one of an inner wall of the arc groove and the second protruding block, a second concave part is arranged on the other one of the inner wall of the arc groove and the second protruding block, and when the second protruding block is inserted into the arc groove and rotated by a preset angle, and the second protruding part is clamped with the second concave part.

In an embodiment of the disclosure, an inner end of the second port is provided with a pipette extending to an inside of the auxiliary agent container.

In an embodiment of the disclosure, a fourth sealing ring is arranged between the first port and the second port.

In an embodiment of the disclosure, a fifth sealing ring is arranged between the container body and the side cover.

In an embodiment of the disclosure, the gun head assembly includes a gun barrel and an outer housing, the outer housing is installed on an outer side of the gun barrel, a right-angle tube is connected with the gun barrel, a first end of the right-angle tube is connected with the gun barrel, and a second end of the right-angle tube passes through an outer side of the outer housing to form the first port.

The technical effects of one or more exemplary embodiments of the disclosure are that the auxiliary agent container is placed horizontally under the gun head assembly, and connected to an outer housing of the gun head assembly through the first connecting part and the second connecting part. An assembly direction of the auxiliary agent container is toward the user. The user only needs to hold a gun handle with one hand and complete assembly operation of the auxiliary agent container with the other hand, which enables the operation to be simpler and more labor-saving. A series of limiting structures and sealing structures are arranged to ensure that the auxiliary agent container is tightly connected with the gun head assembly to avoid a leakage of cleaning auxiliary agent.

One or more embodiments of the disclosure provide a control method of the spray gun and the spray gun that can display a working state of the spray gun in real time to reasonably configure operating power. The control method of the spray gun is applied to the spray gun. The spray gun includes a display screen, a light module, a control switch, a fluid driving element, a battery pack, and a control module. The display screen, the light module, the control switch, the fluid driving element, and the battery pack are electrically connected with the control module respectively;

The control method includes operations as follows.

Power information of the battery pack and state information of the control switch are obtained.

A display state of the display screen, a lighting mode of the light module and operating parameters of the fluid driving element are determined according to the power information of the battery pack, the state information of the control switch, and preset control rules.

The display screen, the light module and the fluid driving element are controlled to work respectively according to the display state of the display screen, the lighting mode of the light module and the operating parameters of the fluid driving element.

In an embodiment of the disclosure, the control switch includes an on-off switch, and determining a display state of the display screen, a lighting mode of the light module and operating parameters of the fluid driving element according to the power information of the battery pack, the state information of the control switch, and preset control rules further includes operations as follows.

When the on-off switch is turned on and power of the battery pack is higher than a preset power, the light module is lit in a first mode, and the fluid driving element works in a standard state.

In an embodiment of the disclosure, the control switch further includes a speed regulation switch, and determining the display state of the display screen, the lighting mode of the light module, and the operating parameters of the fluid driving element according to the power information of the battery pack, the state information of the control switch, and the preset control rules further includes:

When the on-off switch is turned on, the speed regulation switch is turned on and the power of the battery pack is higher than a preset power, the light module is lit in a second mode, and the fluid driving element works in a strong state.

In an embodiment of the disclosure, determining the display state of the display screen, the lighting mode of the light module and the operating parameters of the fluid driving element according to the power information of the battery pack, the state information of the control switch, and preset control rules further includes operations as follows.

When the on-off switch is turned on, the power of the battery pack is higher than the preset power and the speed regulation switch is turned on by clicking, the fluid driving element switches back to the standard state after the fluid driving element works in the strong state for the first preset time.

When the on-off switch is turned on, the power of the battery pack is higher than the preset power and the speed regulation switch is in a pressed state, the fluid driving element keeps in the strong state to work.

In an embodiment of the disclosure, determining the display state of the display screen, the lighting mode of the light module and the operating parameters of the fluid driving element according to the power information of the battery pack, the state information of the control switch, and preset control rules further includes operations as follows.

When the on-off switch is turned on and power of the battery pack is lower than the preset power, the light module is lit in a third mode.

In an embodiment of the disclosure, the light module includes an atmosphere light, and determining the display state of the display screen, the lighting mode of the light module and the operating parameters of the fluid driving element according to the power information of the battery pack, the state information of the control switch, and preset control rules further includes operations as follows.

When the on-off switch is turned off, the atmosphere light is turned off.

In an embodiment of the disclosure, the light module includes an annular light, and determining the display state of the display screen, the lighting mode of the light module and the operating parameters of the fluid driving element according to the power information of the battery pack, the state information of the control switch, and preset control rules further includes operations as follows.

When the on-off switch is turned off and the power of the battery pack is higher than the preset power, the annular module is lit in a fourth mode.

In an embodiment of the disclosure, determining the display state of the display screen, the lighting mode of the light module and the operating parameters of the fluid driving element according to the power information of the battery pack, the state information of the control switch, and preset control rules further includes operations as follows.

When the on-off switch is turned on, the display screen displays the power information of the battery pack in real time.

When the on-off switch is turned off, the display screen is turned off after a second preset time.

In an embodiment of the disclosure, the control method further includes as follows.

Fault information of the spray gun in real time is obtained.

The fault information to the display screen to display is sent.

In an embodiment of the disclosure, before obtaining power information of the battery pack and state information of the control switch, the control method further includes as follows.

Access information of the battery pack is obtained.

When the battery pack is access, the display screen and/or the light module is lit in a third preset time. If the state information of the control switch does not change within the third preset time, the display screen and/or the light module is turned off.

One or more embodiments of the disclosure provide the spray gun, the spray gun includes the display screen, the light module, the control switch, the fluid driving element, the battery pack, and the control module. The display screen, the light module, the control switch, the fluid driving element, and the battery pack are electrically connected with the control module respectively.

The control module includes an information acquisition module, an operation module and an execution module.

The information acquisition module is configured to obtain the power information of the battery pack and the state information of the control switch.

The operation module is configured to determine the display state of the display screen, the lighting mode of the light module and the operating parameters of the fluid driving element according to the power information of the battery pack, the state information of the control switch, and preset control rules.

The execution module is configured to control the display screen, the light module and the fluid driving element to work respectively according to the display state of the display screen, the lighting mode of the light module and the operating parameters of the fluid driving element.

Technical effects of one or more exemplary embodiments of the disclosure are: the power information of the battery is combined with working state information of the water gun, so as to generate visual prompt information based on this information, and display it to the user in real time. The user can have a more intuitive understanding of the power, working state, etc. of the spray gun based on the visual information, which facilitates the user to reasonably allocate the operating power of the spray gun according to actual usage needs, improve an endurance of the spray gun, avoid waste of resources, and improve cleaning efficiency.

One or more embodiments of the disclosure provide the battery pack compartment and a cleaning tool that facilitates a disassembly and assembly of the battery pack. The battery pack compartment includes the body and the compartment cover.

The body is detachably connected with the compartment cover so as to enable the body and the compartment cover together to enclose a space to accommodate the battery pack.

At least one first magnetic unit is arranged at an edge of the body, at least one second magnetic unit is arranged at an edge of the compartment cover, and when the body is connected with the compartment cover, and the first magnetic unit and the second magnetic unit are attractable to each other, so as to enable the body and the bin cover to remain in a connected state.

One of the first magnetic unit and the second magnetic unit is a permanent magnet, and the other one of the first magnetic unit and the second magnetic unit is a ferromagnetic material or a permanent magnet.

In an embodiment of the disclosure, a mounting groove to accommodate the first magnetic unit is arranged on an outer wall at the edge of the body, a fourth notch is formed on a side of the mounting groove close to the edge of the body, and the second magnetic unit is arranged to protrude from the edge of the compartment cover, so as to enable the second magnetic unit to pass through the fourth notch and engage with the first magnetic unit in the mounting groove when the body is connected with the compartment cover.

In an embodiment of the disclosure, an inserting groove is arranged at the edge of the compartment cover, the second magnetic unit is inserted into the inserting groove, a limiting device is arranged between the second magnetic unit and the inserting groove, and the limiting device is configured to enable the second magnetic unit to remain in the inserting groove.

In an embodiment of the disclosure, the limiting device includes a wedge block protruding from an inner wall of the inserting groove and a second limiting groove arranged on the second magnetic unit, and when the second magnetic unit is inserted into the inserting groove, the wedge block is clamped with the second limiting groove.

In an embodiment of the disclosure, a volume of the body is smaller than a volume of the battery pack, so as to enable at least a part of an area of the battery pack to protrude to an outer side of the body when the battery pack is inserted into the body, and the area protruding to the outer side of the body is accommodated in the compartment cover.

In an embodiment of the disclosure, the third restrict part is arranged at the edge of the body, and the fourth restrict part is arranged at the edge of the compartment cover, the third restrict part and the fourth restrict part are configured to limit a relative movement direction of the body and the compartment cover to a first direction in a process of connecting the compartment cover to the body or separating the compartment cover from the body, the first direction is parallel to a direction of an attraction force between the first magnetic unit and the second magnetic unit.

In an embodiment of the disclosure, one of the third restrict part and the fourth restrict part is a second protruding flange, and the other one of the third restrict part and the fourth restrict part is a sinking groove that forms a plug-in fit with the second protruding flange.

In an embodiment of the disclosure, a wiring terminal is arranged at one end of an interior of the body away from the compartment cover.

In an embodiment of the disclosure, an elastic buckle is formed on a side wall of the body, and the elastic buckle is used to be clamped with a clamping groove arranged on a side wall of the battery pack.

One or more embodiments of the disclosure further provide the cleaning tool, and the cleaning tool includes a handle part and a battery pack compartment.

The battery pack compartment is installed at a lower end of the handle part, and the battery pack compartment includes the body and the compartment cover.

The body is fixedly connected with the handle part, the body is detachably connected with the compartment cover so as to enable the body and the compartment cover together to enclose a space to accommodate the battery pack.

At least one first magnetic unit is arranged at an edge of the body, at least one second magnetic unit is arranged at an edge of the compartment cover, and when the body is connected with the compartment cover, and the first magnetic unit and the second magnetic unit are attractable to each other, so as to enable the body and the bin cover to remain in a connected state.

One of the first magnetic unit and the second magnetic unit is a permanent magnet, and the other one of the first magnetic unit and the second magnetic unit is a ferromagnetic material or a permanent magnet.

Beneficial effects of one or more exemplary embodiments of the disclosure are: the magnetic attraction structure is adopted to realize the connection between the battery pack compartment and the compartment cover. There will be no problem of a buckle breakage, and assembly and disassembly are easy. The battery pack is used as a guiding structure when assembling the body and the compartment cover. During assembly, it only needs to put the compartment cover on the battery and then push the compartment cover to accurately connect the compartment cover with the body and accurately engage the first magnetic unit with the second magnetic unit, which enables an installation of the battery compartment cover to be easier and improves usage experience. The third restrict part and the fourth restrict part are matched with each other to prevent a lateral displacement between the body and the compartment cover.

### BRIEF DESCRIPTION OF THE DRAWINGS

FIG. 1 is a perspective view of a spray gun according to at least one embodiment of the disclosure.

FIG. 2 is a perspective cross-sectional view of the spray gun according to at least one embodiment of the disclosure.

FIG. 3 is an exploded view of a display screen mounting structure according to at least one embodiment of the disclosure.

FIG. 4 is a cross-sectional view of the display screen mounting structure according to at least one embodiment of the disclosure.

FIG. 5 is a cross-sectional view of a connecting structure of a gun body assembly and a gun head assembly according to at least one embodiment of the disclosure.

FIG. 6 is an exploded view of the connecting structure of the gun body assembly and the gun head assembly according to at least one embodiment of the disclosure.

FIG. 7 is a partial enlarged view of the connecting structure of the gun body assembly and the gun head assembly according to at least one embodiment of the disclosure.

FIG. 8 is a first perspective view of the gun head assembly according to at least one embodiment of the disclosure.

FIG. 9 is a first exploded view of the gun head assembly according to at least one embodiment of the disclosure.

FIG. 10 is a cross-sectional view in an axial direction of the gun head assembly according to at least one embodiment of the disclosure.

FIG. 11 is a side cross-sectional view of the gun head assembly according to at least one embodiment of the disclosure.

FIG. 12 is a cross-sectional view of a spraying head according to at least one embodiment of the disclosure.

FIG. 13 is an exploded view of the spraying head housing according to at least one embodiment of the disclosure.

FIG. 14 is a cross-sectional view of an area A-A in FIG. 12.

FIG. 15 is an exploded view of the spraying head according to at least one embodiment of the disclosure.

FIG. 16 is a cross-sectional view of a battery pack compartment according to at least one embodiment of the disclosure.

FIG. 17 is a side view of a spraying rod assembly according to at least one embodiment of the disclosure.

FIG. 18 is a side view of the spraying rod assembly with half of an outer housing removed according to at least one embodiment of the disclosure.

FIG. 19 is a cross-sectional view in an axial direction of the spraying rod assembly according to at least one embodiment of the disclosure.

FIG. 20 is a second exploded view of the gun head assembly according to at least one embodiment of the disclosure.

FIG. 21 is a perspective view of a core body according to at least one embodiment of the disclosure.

FIG. 22 is a second perspective view of the gun head assembly according to at least one embodiment of the disclosure.

FIG. 23 is a third exploded view of the gun head assembly according to at least one embodiment of the disclosure.

FIG. 24 is an exploded view of an auxiliary agent container according to at least one embodiment of the disclosure.

FIG. 25 is a partial cross-sectional view of a first connecting part and a second connecting part according to at least one embodiment of the disclosure.

FIG. 26 is a flowchart of a control method of the spray gun according to at least one embodiment of the disclosure.

FIG. 27 is a flowchart of a fault information feedback control of the spray gun according to at least one embodiment of the disclosure.

FIG. 28 is a flowchart of a determination of operating parameters of the spray gun according to at least one embodiment of the disclosure.

FIG. 29 is a flowchart of a specific control process of the spray gun according to at least one embodiment of the disclosure.

FIG. 30 is a structural block view of a control module according to at least one embodiment of the disclosure.

FIG. 31 is a perspective view of a cleaning tool according to at least one embodiment of the disclosure.

FIG. 32 is a perspective cross-sectional view of the battery pack compartment according to at least one embodiment of the disclosure.

FIG. 33 is a partial enlarged view of an area I in FIG. 32.

FIG. 34 is an exploded view of an assembly position of the battery pack compartment and the cleaning tool according to at least one embodiment of the disclosure.

FIG. 35 is a perspective view of a compartment cover according to at least one embodiment of the disclosure.

### DETAILED DESCRIPTION

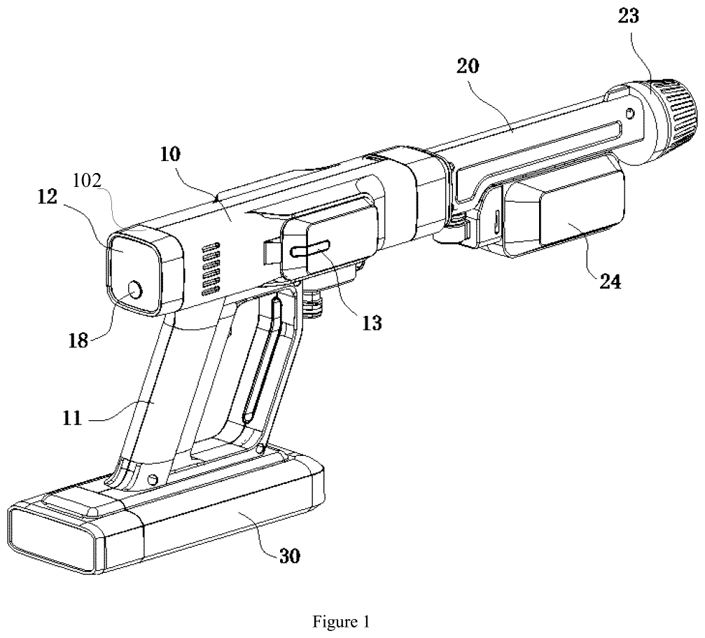

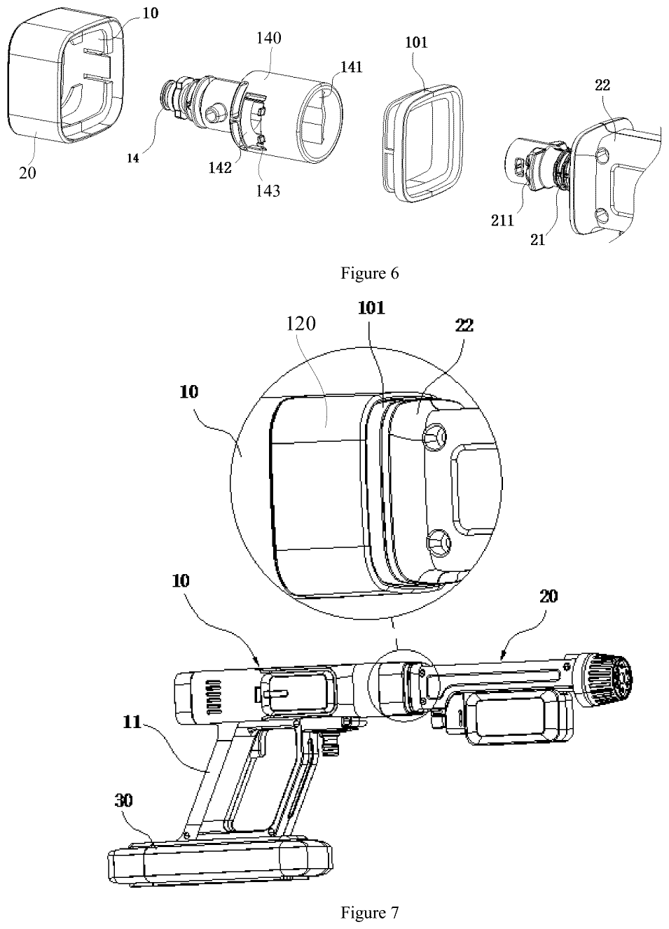

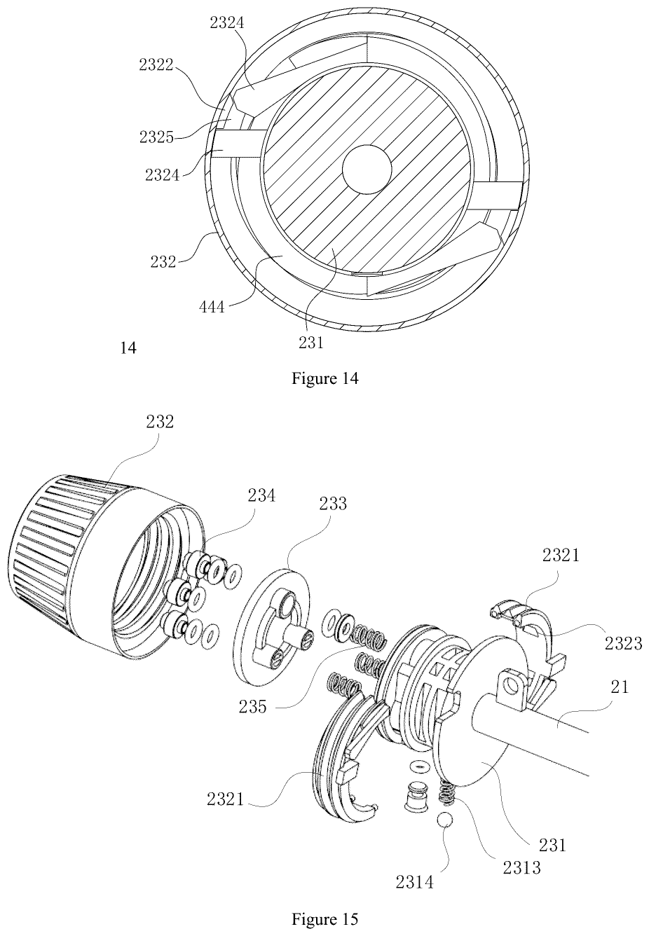

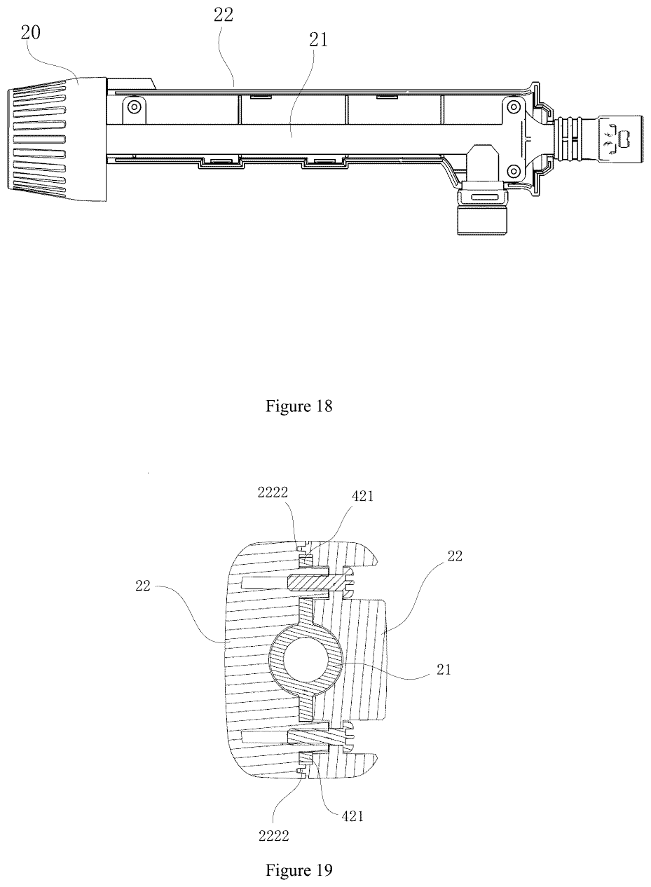

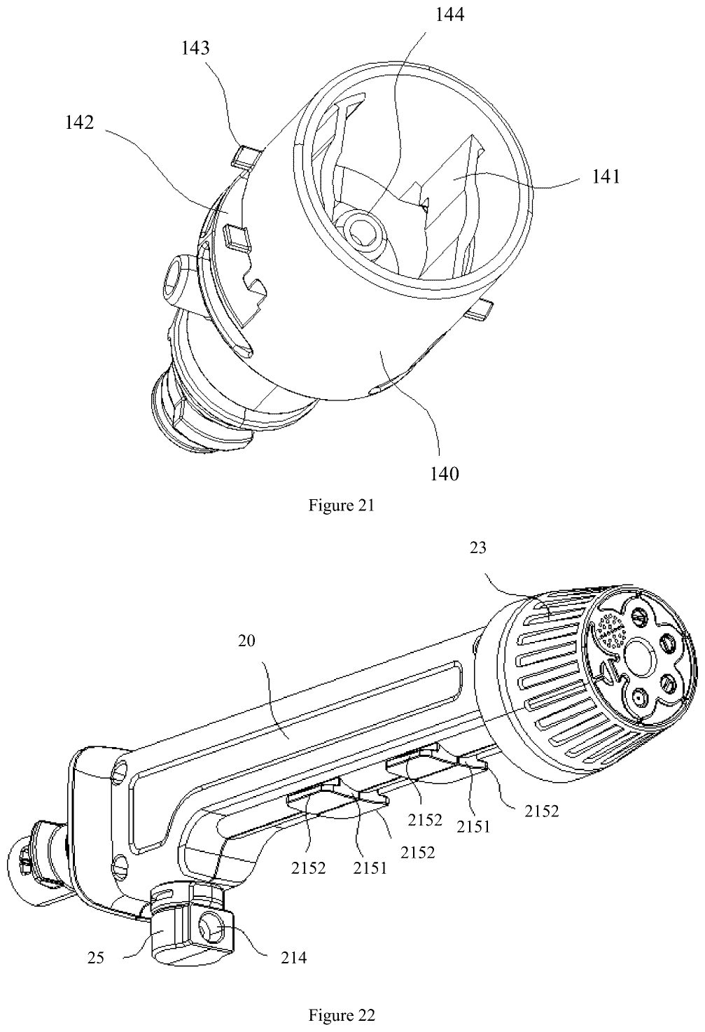

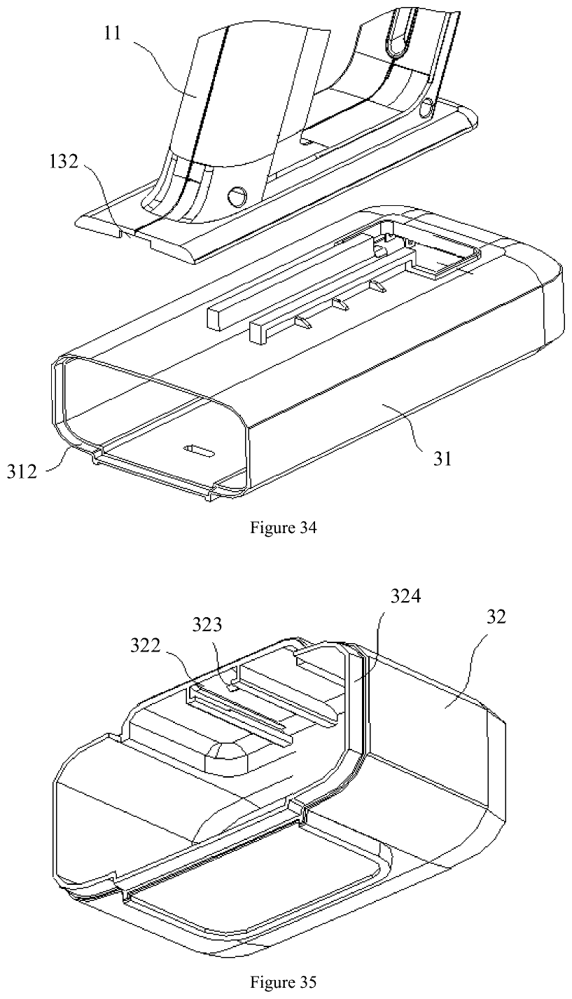

Please refer to FIG. 1 through FIG. 35. The following describes the implementation of the disclosure through specific embodiments, and those skilled in the art can easily understand other advantages and effects of the disclosure from the content disclosed in this specification. The disclosure may also be implemented or applied through other different specific embodiments. Various details in this specification may also be modified or changed based on different viewpoints and applications without departing from the disclosure. It should be noted that, the following embodiments and the features in the embodiments can be combined with each other without conflict.

It should be noted that drawings provided in the embodiments are only illustrative of a basic idea of the disclosure. The drawings only show assemblies related to the disclosure instead of drawing according to the number, shape and size of the assemblies in actual implementation. In actual implementation, the type, quantity and ratio of each assembly may be changed at will, and a layout of the assemblies may also be more complicated.

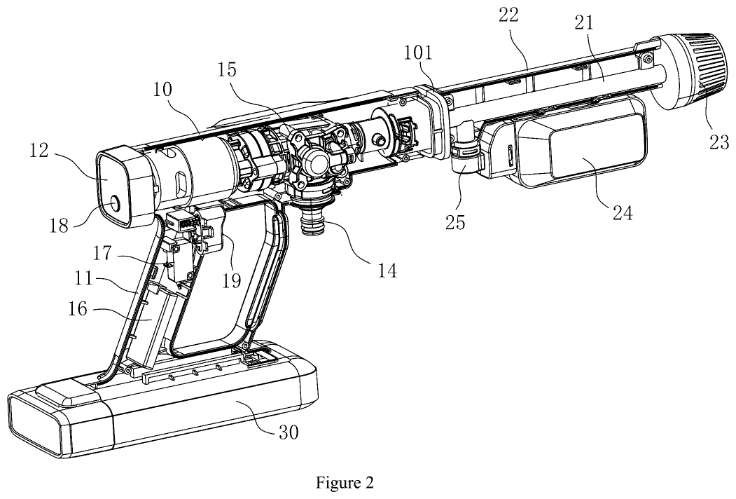

Please refer to FIG. 1 and FIG. 2. Technical solutions of this disclosure are described in detail below in conjunction with a specific embodiment. FIG. 1 shows a spray gun, the spray gun includes a gun body, a flow passage 14, a fluid driving element 15, a control module 16, a visual interface module, a switch assembly and a battery pack.

Please refer to FIG. 1 and FIG. 2. The flow passage 14 is formed in the gun body. A first end of the flow passage 14 passes through the gun body to form a water inlet of the spray gun on an outside of the gun body, and a second end of the flow passage 14 is communicated with the gun head assembly 20. The fluid driving element 15 is installed in the gun body, and the fluid driving element 15 may be, for example, a water pump and a motor. The fluid driving element 15 is connected in series with the flow passage 14 to drive fluid in the flow passage 14 to flow.

The control module 16 is electrically connected with the fluid driving element 15. The control module 16 may be, for example, a PCB control board integrated with electric components such as a single-chip microcomputer. The visual interface module is installed on the gun body and exposed on a surface of the gun body. The visual interface module may be, for example, a display screen 12 or an atmosphere light 13 that can represent different information in different lighting states or different colors.

The visual interface module is electrically connected with the control module 16. The switch assembly is electrically connected with the control module 16. The switch assembly at least includes an on-off switch 17 and a speed regulation switch 18. The battery pack is electrically connected with the control module 16. The control module 16 is configured to obtain power information of the battery pack and/or working state information of the fluid driving element 15, and display the power information of the battery pack and/or the working state information of the fluid driving element 15 through the visual interface module.

It may be understood that the visual interface module can display remaining power of the battery pack and a working state of the fluid driving element 15 in real time visual interface module. A user can reasonably set working power of the spray gun according to the remaining power and turn on a high-power mode when necessary, for example, to clean stubborn stains. This can reasonably distribute power of the battery pack, improve an endurance of the spray gun, and avoid battery replacement or charging in a middle of a process, and thus improving work efficiency.

Please refer to FIG. 1 and FIG. 2. The gun body includes a gun body assembly 10, a gun head assembly 20 and a battery pack compartment 30. The gun body assembly 10 is enclosed by a housing, and is formed with a handle part 11. The fluid driving element 15, the control module 16 and the switch assembly are installed on the gun body assembly 10. The gun head assembly 20 is detachably installed on a front end of the gun body assembly 10, and a front end of the gun head assembly 20 is provided with a spraying head 23. The battery pack compartment 30 is located at a lower end of the handle part 11, and the battery pack is installed in the battery pack compartment 30. The handle part 11 is provided with a trigger 19 for triggering the on-off switch 17.

Please refer to FIG. 1. The visual interface module includes the display screen 12 and/or the atmosphere light 13, the display screen 12 is installed at a rear end of the gun body assembly 10, and the atmosphere light 13 is installed on two sides of the gun body assembly 10. The speed regulation switch 18 is installed in a position touchable by the thumb of a user when the user holds the handle part, for example, the speed regulation switch 18 is installed on a bottom of the display screen 12.

In this embodiment, the control module 16 may, for example, use a following method to prompt power of the battery pack and a related working state of the spray gun: when the battery is inserted into the battery compartment, the display screen 12 lights up, and the atmosphere lights 13 on two sides flash; when a consumer needs a higher pressure for cleaning, a TURBO button on the display screen 12 (which means the speed regulation switch 18) may be pressed. At this time, a cleaning machine is in a strong working state, and the display screen 12 and the atmosphere lights 13 on the two sides display a green flashing state, which may last for 6-30 seconds. If the TURBO button is not pressed, the cleaning machine is in a standard working state, and the display screen 12 and the atmosphere lights 13 on the two sides display a green steady state. When battery power is lower than a set value, the display screen 12 and the atmosphere lights 13 on the two sides display a red steady state. When the cleaning machine fails, the display screen 12 and the atmosphere lights 13 on the two sides display a red flashing state.

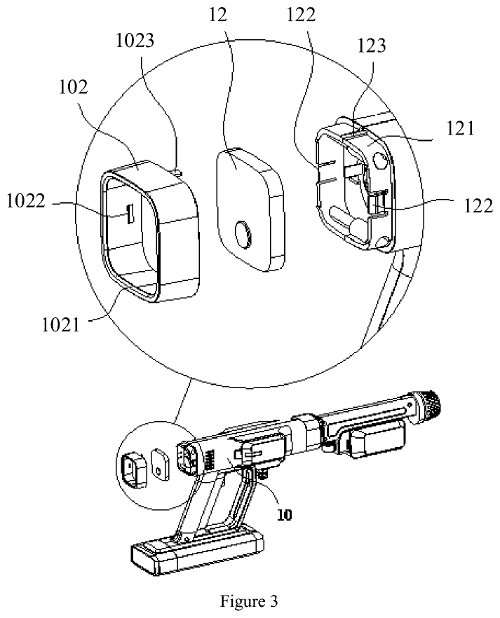

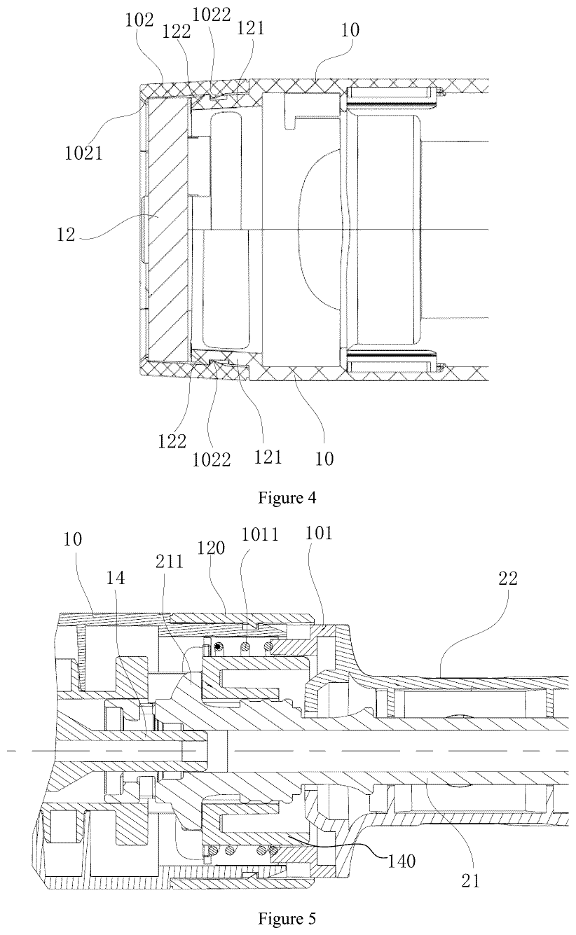

Please refer to FIG. 3 and FIG. 4. A clamping ring 102 is provided at the rear end of the gun body assembly 10, the clamping ring 102 is detachably connected with the gun body assembly 10, the display screen 12 is accommodated in the clamping ring 102, a first protruding flange 1021 is arranged on an inner wall of the clamping ring 102, and the first protruding flange 1021 abuts against an outer edge of the display screen 12 to limit the display screen 12 within the clamping ring 102. The disclosure adds the clamping ring 102 on an outside of the gun body assembly 10 and connects the clamping ring 102 with a body of the gun body assembly 10 through the buckle, so that the display screen 12 is pressed and installed onto the gun body assembly 10, thereby avoiding damage to the gun body assembly 10 and the display screen 12 when disassembling a screen.

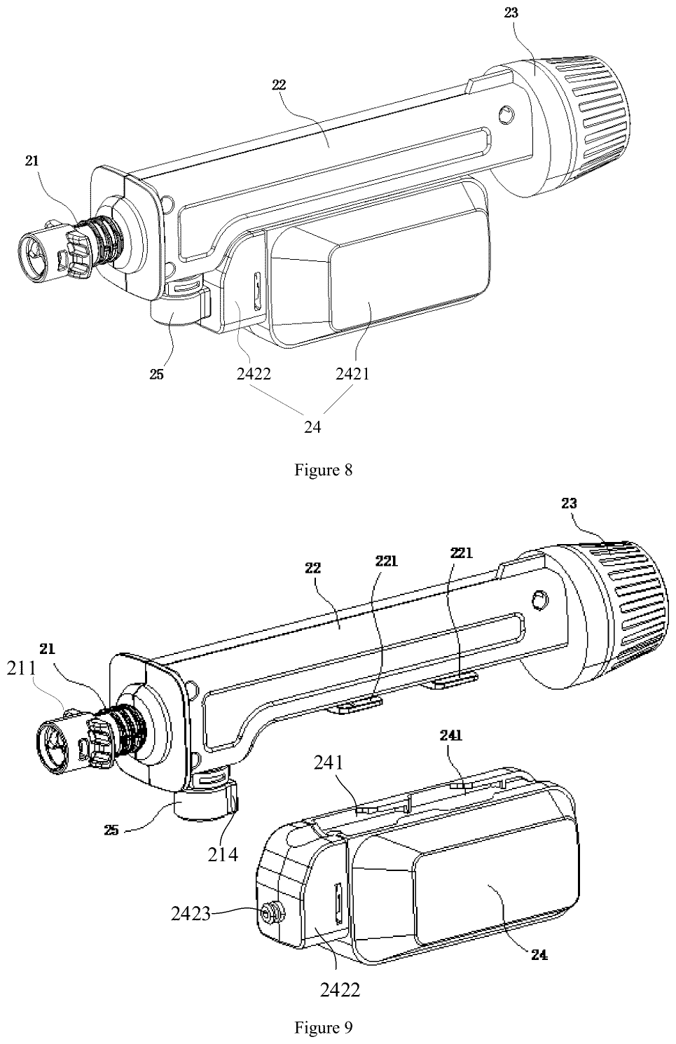

Please refer to FIG. 8 through FIG. 11. The gun head assembly 20 includes a gun barrel 21, an outer housing 22, the spraying head 23 and an auxiliary agent container 24. The outer housing 22 covers an outside of the gun barrel 21. The spraying head 23 is connected with a front end of the gun barrel 21. The auxiliary agent container 24 is installed on the outer housing 22 and is communicated with the gun barrel 21 through a pipeline. The outer housing 22 of the disclosure is not restricted by the pressure-bearing performance requirement and may be made of materials that are beneficial to the appearance, thereby avoiding direct exposure of the gun barrel 21 to the outside, improving the integrity and appearance consistency of a product, allowing the variety of color options, and providing the rich selection space for product industrial design and achieving the flexible and changeable appearance.

Please refer to FIG. 5 through FIG. 7. A quick-connector is arranged between the gun barrel 21 and the flow passage 14 inside the gun body assembly 10, a floating ring 101 is arranged on the gun body assembly 10 or the gun head assembly 20, the floating ring 101 is movably connected with the gun body assembly 10 or the gun head assembly 20 along an axis direction of the gun barrel 21, an elastic element 1011 is arranged between the floating ring 101 and the gun body assembly 10 or the gun head assembly 20. The elastic element 1011 includes but is not limited to a compression spring. When the quick-connectors are connected with each other, and the elastic element 1011 is capable of being compressed to enable the floating ring 101 to press against an end face of the gun body assembly 10 or the gun head assembly 20.

In an embodiment of the disclosure, the quick-connector includes a limiting hole 141 with a non-circular cross-section arranged on the gun body assembly 10 and a limiting head 211 arranged at an end part of the gun barrel 21 and matched with a cross-section of the limiting hole 141. A third notch 142 is arranged on a hole wall of the limiting hole 141. When the gun barrel 21 is inserted into the flow passage 14 in the gun body assembly 10, the limiting head 211 is aligned with the third notch 142. At this time, the limiting head 211 is rotated to enable the cross-section of the limiting head 211 to be misaligned with the cross-section of the limiting hole 141, so as to block the limiting head 211 in the third notch 142.

It may be understood that, the floating ring 101 can compensate for the assembly gap, improve a stability between the gun body assembly 10 and the gun head assembly 20, and enhance an appearance quality of the spray gun.

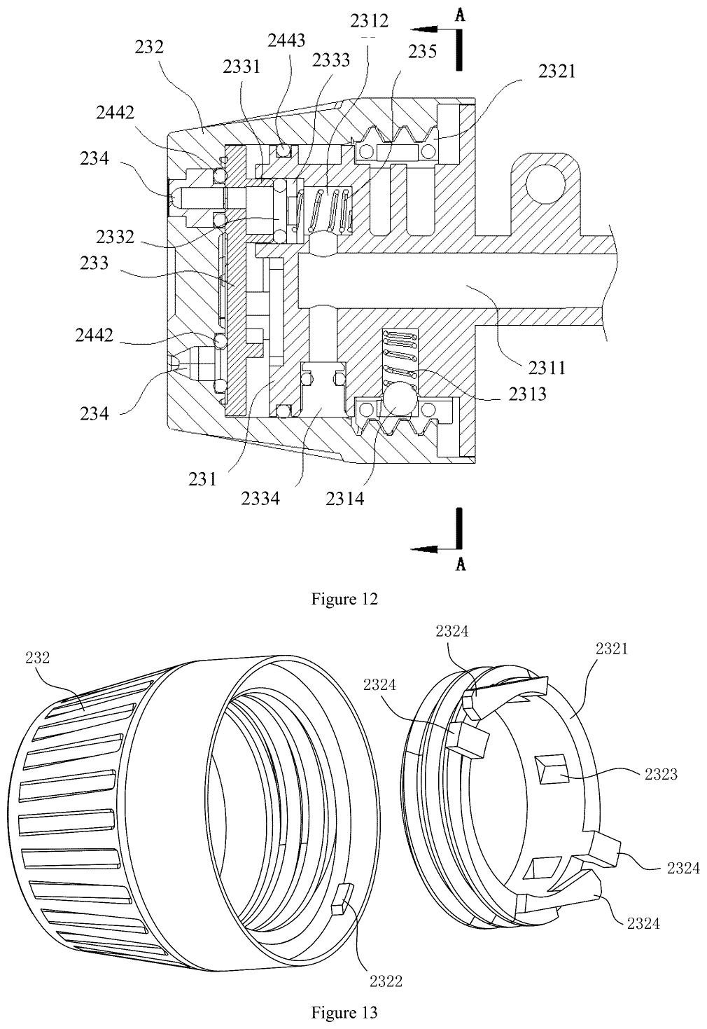

Please refer to FIG. 12 through FIG. 15. The gun head assembly 20 is coaxially arranged with the gun barrel 21, and the spraying head 23 includes a fixing component 231 and a spraying head housing 232. The spraying head housing 232 is a rotating component. The fixing component 231 is fixedly connected with the gun barrel 21. A first flow passage 2311 coaxially arranged with an axis of the gun barrel 21 and a second flow passage 2312 eccentrically arranged relative to the axis of the gun barrel 21 are formed in the fixing component 231. The spraying head housing 232 is rotatably connected with the fixing component 231, a plurality of spray nozzles 234 are circumferentially arranged at a front end of the spraying head housing 232, and when the spraying head housing 232 rotates relative to the fixing component 231, each of the spray nozzle 234 is capable of being alternately communicated with the second flow passage 2312.

Please refer to FIG. 12 through FIG. 15. In a specific embodiment, the first flow passage 2311 passes through a rear end of the fixing component 231, and the second flow passage 2312 passes through a front end of the fixing component 231. The spraying head housing 232 is coaxially arranged with the fixing component 231 and the spraying head housing 232 and the fixing component 231 are rotatably connected with each other. The spraying head housing 232 at least coves the front end of the fixing component 231, and a plurality of spray nozzles 234 is arranged on a housing wall of the spraying head housing 232 opposite to the front end of the fixing component 231. Each of the spray nozzles 234 is arranged at intervals along a circumferential direction of the first flow passage 2311, and when the spraying head housing 232 rotates relative to the fixing component 231, each spray nozzle 234 is alternately connectable with the second flow passage 2312.

Please refer to FIG. 12 through FIG. 15. The first flow passage 2311 is a blind hole formed along a center of the fixing component 231, and the second flow passage 2312 is another blind hole eccentrically arranged relative to the first flow passage 2311. The two blind holes may be communicated with each other through a radial hole, for example.

Please refer to FIG. 12 through FIG. 15. The spraying head 23 in the disclosure realizes a symmetrical design relative to the gun barrel 21, meets different industrial styling requirements, and when switching the spray nozzle 234, the spraying head housing 232 can be rotated along the axis of the gun barrel 21, which enables an adjustment to be more convenient. In a specific embodiment, the fixing component 231 may be integrally formed with the gun barrel 21, or it may be separately processed and assembled into one, for example, the fixing component 231 is connected with the gun barrel 21 by a threaded connection.

Please refer to FIG. 12 through FIG. 15. The gun head assembly 20 further includes a floating plate 233 and a first elastic unit 235. The floating plate 233 is located between the front end of the fixing component 231 and an inner wall of the spraying head housing 232. The floating plate 233 is movably arranged along an axial direction of the fixing component 231. A through hole is arranged on the floating plate 233 at a position corresponding to the second flow passage 2312. The first elastic unit 235 is assembled so that an elastic force of the first elastic unit 235 acts forward on the floating plate 233 to keep the floating plate 233 in a state of contact with the inner wall of the spraying head housing 232. It may be understood that, the floating plate 233 is tightly attached to the inner wall of the spraying head housing 232 under an action of the first elastic unit 235, ensuring that the spray nozzles 23 other than the working spray nozzle 23 are in a completely closed state, preventing water from penetrating into other spray nozzles 234 through a gap between the spraying head housing 232 and the fixing component 231 and causing leakage of cleaning liquid. In a specific embodiment, the first elastic unit 235 may be the compression spring, for example.

Please refer to FIG. 12 through FIG. 15. The spraying head housing 232 further includes a cylindrical part covering a side surface of the fixing component 231, and a third sealing ring 2443 is arranged between an inner wall of the cylindrical part and the side surface of the fixing component 231. In a specific embodiment, an annular groove is arranged on the side surface of the fixing component 231, a limiting ring 2321 is arranged in the annular groove, the limiting ring 2321 is rotatably matched with the fixing component 231 relatively, the spraying head housing 232 is relatively fixedly connected with the limiting ring 2321 in a detachable manner, a limiting unit is arranged between the limiting ring 2321 and the fixing component 231, and the limiting unit is configured to keep the spraying head housing 232 in a state that any of the spray nozzle 234 on the spraying head housing 232 is communicated with the second flow passage 2312, and to release the spraying head housing 232 when the spraying head housing 232 is subjected to a torque greater than a preset value. The disclosure realizes a switching of the spray nozzle 234 by rotating the spraying head housing 232. In order to ensure that each spray nozzle 234 can be correctly aligned with the second flow passage 2312 each time the spray nozzle 234 is switched, the disclosure arranges a limiting device between the spraying head housing 232 and the fixing component 231. The limiting device can enable the spraying head housing 232 to produce an obvious sense of frustration every time it rotates a certain angle. This specific angle is an interval angle between adjacent spray nozzles 234. The limiting device can further produce a certain holding force on the spraying head housing 232 to prevent the spraying head housing 232 from being offset under an action of high-pressure water flow.

Please refer to FIG. 12 through FIG. 15. In a specific embodiment, the limiting unit includes a limiting block 2314 movably arranged along a radial direction of the fixing component 231, at least an outer end of the limiting block 2314 has a smooth outer contour, a second elastic unit 2313 is arranged between the limiting block 2314 and the fixing component 231, the second elastic unit 2313 is configured so that an elastic force there of acting on the limiting block 2314 is capable of driving the limiting block 2314 to move outward along the radial direction of the fixing component 231, a first limiting groove 2323 matched with the limiting block 2314 is arranged on an inner wall of the limiting ring 2321, there is a plurality of the first limiting grooves 2323, and each of the first limiting grooves 2323 is arranged at intervals along a circumferential direction of the limiting ring 2321. The limiting block 2314 may be, for example, a steel ball, and the first limiting groove 2323 can be, for example, set to a V-shaped groove. When the steel ball is about to reach the V-shaped groove, the steel ball can slide down to a bottom of the V-shaped groove under a guidance of an inclined surface of the V-shaped groove, so that when the spraying head housing 232 switches between different working stations, an obvious suction feeling can be generated.

Please refer to FIG. 12 through FIG. 15. The limiting ring 2321 is formed by splicing two half rings. The cylindrical part is threaded with the limiting ring 2321, a locking block 2322 is arranged on the inner wall of the cylindrical part, a locking groove 2325 is arranged on an edge of the limiting ring 2321, the locking groove 2325 is formed between two cantilevers 2324, a first one of the two cantilevers 2324 is fixedly connected with the limiting ring 2321, and a second one of the two cantilevers 2324 is elastically connected with the limiting ring 2321, and the second cantilever 2324 is configured so that the locking block 2322 is capable of pushing the second cantilever 2324 away to fall into the locking groove 2325 during a process of a threaded connection between the cylindrical part and the limiting ring 2321, and the second cantilever 2324 is capable of preventing the locking block 2322 from moving out of the locking groove 2325.

It may be understood that, the spraying head housing 232 is connected with the fixing component 231 in real time through the limiting ring 2321, which enables an installation to be more convenient. A specific installation process is as follows: first, the second elastic unit 2313 and the limiting block 2314 are installed on the fixing component 231, then two half rings of the limiting ring 2321 are clamped in an annular groove set on the fixing component 231, and then the spraying head housing 232 is screwed on the limiting ring 2321. During a screwing process, the locking block can slide into the locking groove, thereby realizing a synchronous rotation between the spraying head housing 232 and the limiting ring 2321, and preventing the spraying head housing 232 from loosening from the limiting ring 2321.

Please refer to FIG. 8 through FIG. 11. A right-angle tube 25 is connected with the gun barrel 21, the right-angle tube 25 passes through the outer housing 22 and forms an auxiliary agent container connector parallel to the gun barrel 21 on an outside of the outer housing 22, the auxiliary agent container 24 is connected with the auxiliary agent container connector along a direction parallel to the gun barrel 21, a sliding clamping mechanism is arranged between the outer housing 22 and the auxiliary agent container, the sliding clamping mechanism includes a first connecting part 221 fixed with the outer housing 22 and a second connecting part 241 fixed with the auxiliary agent container 24. The first connecting part 221 includes but is not limited to a T-shaped sliding block, and the second connecting part 241 is matched and connected with the first connecting part 221 and includes but not limited to a T-shaped sliding groove. A limiting protrusion is arranged on the first connecting part 221, and a limiting groove matched with the limiting protrusion is arranged on an inner wall of the second connecting part 241. In a specific embodiment, the auxiliary agent container 24 is further provided with a pipette 242, and the pipette 242 is communicated with the right-angle tube 25. The disclosure places the auxiliary agent container 24 horizontally below an assembly of the gun barrel 21. An assembly direction of the auxiliary agent container 24 is toward the user. The user only needs to hold a gun handle with one hand and complete assembly operation of the auxiliary agent container with the other hand, which enables the operation to be simpler and more labor-saving.

The auxiliary agent container 24 is used to store cleaning auxiliary agent. According to Bernoulli's principle, when water flows at high speed in the gun barrel 21, a negative pressure will be generated in the right-angle tube 25. Therefore, when the auxiliary agent container 24 is communicated with the right-angle tube 25, the cleaning auxiliary agent in the auxiliary agent container 24 can be sucked into the first flow passage 2311, and the cleaning auxiliary agent is mixed with the water and then sprayed out from the spraying head 23.

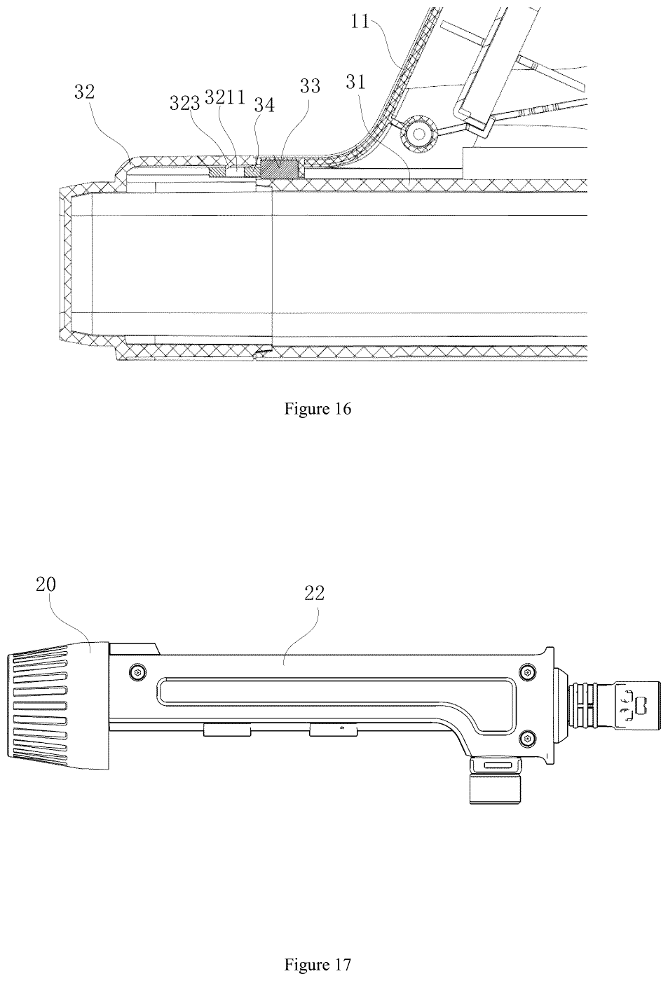

Please refer to FIG. 16. The battery pack compartment 30 includes a body 31 and a compartment cover 32, and the compartment cover 32 and the body 31 are respectively provided with magnetic units that can attract each other. The magnetic units include a first magnetic unit 33 and a second magnetic unit 34. The first magnetic unit 33 includes but is not limited to a permanent magnet, and the second magnetic unit is a patch. The disclosure adopts a magnetic attraction structure to realize a connection between the battery pack compartment 30 and the compartment cover 32. There will be no problem of a buckle breakage, and assembly and disassembly are very easy.

In summary, the disclosure can display remaining power of the battery pack and a working state of the fluid driving element 15 in real time through the visual interface module. A user can reasonably set working power of the spray gun according to the remaining power and turn on a high-power mode when necessary, for example, to clean stubborn stains. This can reasonably distribute power of the battery pack, improve an endurance of the spray gun, and avoid battery replacement or charging in a middle of a process, and thus improving work efficiency.

The floating ring 101 can compensate for the assembly gap, improve a stability between the gun body assembly 10 and the gun head assembly 20, and enhance an appearance quality of the spray gun.

The disclosure places the auxiliary agent container 24 horizontally below the assembly of the gun barrel 21. The assembly direction of the auxiliary agent container 24 is toward the user. The user only needs to hold the gun handle with one hand and complete assembly operation of the auxiliary agent container with the other hand, which enables the operation to be simpler and more labor-saving.

Considering that during the assembly process of the cleaning tool, due to the influence of appearance factors, the gun body assemblies of the body are mostly connected by a buckle, and the display screen is generally fixed inside the gun body assembly. When rework is required, only the entire gun body assembly should be disassembled, which may easily cause the gun body assembly to be scrapped or the display screen to be damaged.

Please refer to FIG. 1, FIG. 3 and FIG. 4. The disclosure further provides a display screen mounting structure of the spray gun, which includes the gun body assembly 10, the clamping ring 102 and the display screen 12. It may be understood that, the disclosure aims to improve an installation structure of the display screen 12 of the spray gun. Therefore, following content only describes in detail about a structure of the spray gun associated with the display screen 12. Other structures not described in detail may refer to the above-mentioned spray gun.

Please refer to FIG. 1 through FIG. 4. A casing of the gun body assembly 10 serves as a covering component for covering a surface of the spray gun. It may be understood that, a main function of the casing of the gun body assembly 10 is to be an appearance of the spray gun, as well as to include a supporting structure and connecting structure of each module of the spray gun. A shape and internal structure of the casing of the gun body assembly 10 may be designed according to a distribution of internal parts and appearance requirements, and a material of the casing of the gun body assembly 10 is not particularly limited, for example, it may be a plastic material, a metal material, or a composite material composed of plastic and rubber, or a composite material composed of plastic, rubber, metal, etc. In the illustrated embodiment of the disclosure, the casing of the gun body assembly 10 may, for example, be formed with a gun body part, a barrel part, a handle part, and a battery pack compartment part. These parts may be connected with each other as a whole, or may be individually molded and then assembled. Considering an actual molding process and assembly convenience of the gun body assembly 10, the gun body assembly 10 is divided into two parts along a center dividing surface of the spray gun, and the two parts of the gun body assembly 10 are manufactured and molded separately and then assembled into one.

Please refer to FIG. 1 through FIG. 4. The clamping ring 102 is detachably connected with the gun body assembly 10. The clamping ring 102 is mainly used to accommodate and fix the display screen 12. It may be understood that in a description of the disclosure, describing this component as the clamping ring 102 is only to provide an expression that is easier to understand, and does not mean that it must be a housing-like structure. For example, the clamping ring 102 may also be in a shape similar to a buckle or a claw. In the illustrated embodiment of the disclosure, the clamping ring 102 is configured as an annular housing, which may be understood as a preferred shape arrangement, so that it can be better spliced with the gun body assembly 10 and ensure an integrity of the appearance of the spray gun.

Please refer to FIG. 1 through FIG. 4. The display screen 12 is installed on the clamping ring 102 in such a way that its display surface can be exposed. It may be understood that a main function of the display screen is to display some main operating parameters of the spray gun, so its display surface needs to be able to be displayed to an outside. Apart from this, there are no other special restrictions on an installation form of the display screen 12. For example, the display surface may face a side surface of the spray gun or a rear of the spray gun. However, considering a convenience of practical application, in the illustrated embodiment of the disclosure, the display screen 12 is installed on a rear side of the spray gun. This enables the user to obtain the operating parameters of the spray gun at any time when the spray gun is in use.

The disclosure adds the clamping ring 102 on an outside of the gun body assembly 10 and sets the clamping ring 102 and the body of the gun body assembly 10 as a detachable structure, so that the display screen 12 is pressed and installed onto the gun body assembly 10, thereby reducing a scrap rate of the gun body assembly 10 caused by screen problems, shortening the rework time, and improving the assembly efficiency.

Please refer to FIG. 3 through FIG. 4. A first limiting part 122 is arranged on the gun body assembly 10, a second limiting part 1022 is arranged on the clamping ring 102, the first limiting part 122 and the second limiting part 1022 are configured such that when the clamping ring 102 and the gun body assembly 10 are in a connected state, the first limiting part 122 and the second limiting part 1022 are capable of blocking each other to prevent the clamping ring 102 from separating from the gun body assembly 10. It may be understood that, main functions of the first limiting part 122 and the second limiting part 1022 is to maintain a reliable connection between the clamping ring 102 and the gun body assembly 10. There is no special restriction on a limiting method between the first limiting part 122 and the second limiting part 1022, but a convenience during disassembly and a reliability during connection should be considered. For example, the first limiting part 122 and the second limiting part 1022 may be screws and screw holes, respectively, or elastic buckles and clamping grooves. However, considering the convenience during disassembly, the disclosure preferably adopts a buckle-type limiting structure.

Please refer to FIG. 3 through FIG. 4. At least one of the first limiting part 122 and the second limiting part 1022 is configured to be capable of deforming or displacing under an action of external force so as to release a mutual blocking state between the first limiting part 122 and the second limiting part 1022. For example, the first limiting part 122 may be set as a movable latch, and the second limiting part 1022 may be set as a inserting hole matched with the latch, so that when the latch is pulled out of the inserting hole, a limitation between the first limiting part 122 and the second limiting part 1022 can be released. Or as in the illustrated embodiment of the disclosure, the first limiting part 122 may be set as an elastic component, and a deformation of the elastic component may be used to release the limitation between the first limiting part 122 and the second limiting part 1022. Compared with the former, the latter is simpler in structure and is therefore used as a preferred embodiment of the disclosure.

Please refer to FIG. 1 through FIG. 4. In a specific embodiment, the clamping ring 102 is an annular structure, and an annular plug-in part 121 is formed on the gun body assembly 10, the plug-in part 121 is plugged into an inner wall of the clamping ring 102. It may be understood that, in this embodiment, a relative position between the clamping ring 102 and the gun body assembly 10 is mainly determined by a matching between the annular plug-in part 121 and the inner wall of the clamping ring 102. The annular plug-in part 121 limits a separation direction of the clamping ring 102, and the first limiting part 122 and the second limiting part 1022 only need to limit the clamping ring 102 and the gun body assembly 10 along the separation direction to prevent the clamping ring 102 from detaching from the gun body assembly 10.

Please refer to FIG. 3 through FIG. 4. In a specific embodiment of the disclosure, the second limiting part 1022 includes a second wedge part arranged on the inner wall of the clamping ring 102, the first limiting part 122 includes a first wedge part arranged on an outer wall of the plug-in part 121, notches are formed on the plug-in parts 121 on two sides of the first limiting part 122 so that an area where the first limiting part 122 is located forms a cantilever structure. It may be understood that, in this embodiment, the second limiting part 1022 includes a partial area of the annular plug-in part 121. In order to enable this partial area to be more easily produce an elastic deformation, the disclosure arranges notches on two sides of this partial area so that this partial area forms a cantilever structure. In order to be matched with the first wedge part, the second wedge part is arranged on the inner wall of the clamping ring 102 in this embodiment. It may be understood that in addition to using the second wedge part, the disclosure may also use a clamping groove to be matched with the first limiting part 122. A specific method is to arrange a concave groove on the inner wall of the clamping ring 102. When the clamping ring 102 is connected with the gun body assembly 10, the first limiting part 122 is clamped in the concave groove, which can also achieve a limitation between the clamping ring 102 and the gun body assembly 10. Similarly, in the disclosure, positions of the second limiting part 1022 and the first limiting part 122 may be interchanged. For example, an elastic buckle is arranged on the clamping ring 102, and at the same time a protrusion or a concave groove that matched with the elastic buckle is arranged on the gun body assembly 10.

Please refer to FIG. 4. In a specific embodiment of the disclosure, one of the clamping ring 102 and the plug-in part 121 is provided with a positioning pin 1023, and the other one of the clamping ring 102 and the plug-in part 121 is provided with a positioning groove 123 plug-in fitted with the positioning pin 1023. When the clamping ring 102 is assembled with the gun body assembly 10, the positioning pin 1023 may be inserted into the positioning groove 123 to determine a relative position between the clamping ring 102 and the gun body assembly 10, and then the clamping ring 102 is plugged into the annular plug-in part 121, which is more conducive to quickly finding the plug-in position when assembling the clamping ring 102.

Please refer to FIG. 1 through FIG. 4. The clamping ring 102 is connected with the gun body assembly 10 to form a tail end of the spray gun. In this embodiment, the display screen 12 is installed on a rear side of the spray gun. This enables the user to more easily obtain information such as the operating parameters of the spray gun when the spray gun is in use.

Please refer to FIG. 4. In a specific embodiment of the disclosure, a step part is formed between the plug-in part 121 and the gun body assembly 10, and a thickness of the step part is consistent with a thickness of the clamping ring 102, so that when the clamping ring 102 is connected with the gun body assembly 10, an outer surface of the clamping ring 102 is flush with an outer surface of the gun body assembly 10, thereby ensuring the appearance of the spray gun.

Please refer to FIG. 3 through FIG. 4. An end of the clamping ring 102 away from the gun body assembly 10 is provided with a first protruding flange 1021 protruding inward, and the first protruding flange 1021 blocks an edge of the display screen 12 to limit the display screen 12 within the clamping ring 102. In this embodiment, the display screen 12 is limited between the protruding flange 1021 and an end face of the annular plug-in part 121. It may be understood that in order to better fix the display screen 12, a distance between the protruding flange 1021 and the end face of the annular plug-in part 121 is preferably consistent with a thickness of the display screen 12, or an elastic buffer pad is arranged between the display screen 12 and the annular plug-in part 121 to eliminate a gap between the display screen 12 and the annular plug-in part 121.

Please refer to FIG. 3 and FIG. 4. In a specific embodiment of the disclosure, a through hole is formed in an area of the gun body assembly 10 connected with the clamping ring 102, so that a mounting area of the display screen 12 is communicated with an inner area of the gun body assembly 10. It may be understood that, the display screen 12 needs to be connected with a working module inside the spray gun through a wire, and the through holes in this embodiment are mainly used for the wire to pass through.

In summary, the disclosure adds the clamping ring 102 on the outside of the gun body assembly 10 and connects the clamping ring 102 with the body of the gun body assembly 10 through a buckle, so that the display screen 12 is pressed and installed onto the gun body assembly 10, thereby reducing the scrap rate of the gun body assembly 10 caused by the screen problems, shortening the rework time, and improving the assembly efficiency.

As one of the various accessories of the high-pressure cleaning machine, the multi-in-one spray nozzle (spraying rod) integrates the multiple spray nozzles and realizes the integration of multiple water shapes in one, allowing the customers to flexibly switch the cleaning modes according to the needs of different cleaning conditions. Considering that a water inlet position of the conventional multi-in-one spray nozzle on the market is located on one side of the central axis of the spraying head, the overall shape is asymmetrical. When adjusting the spraying head, a force on the spraying rod is uneven. And conventional multi-in-one spray rods on the market are limited by functional requirements, and a rod body material is usually nylon fiberglass. Its manufacturing process cannot meet higher appearance design requirements, such as mirror highlights, colored parts, etc. One or more embodiments of the disclosure provide the gun head assembly and a spraying rod assembly, both of the gun head assembly and the spraying rod assembly are with symmetrical overall appearances and convenient for spray nozzle adjustment.

Please refer to FIG. 17. The figure shows a spraying rod assembly structure, which may be used, for example, in the spray gun. In a specific embodiment, the spraying rod assembly serves as a gun head part of the spray gun, the spray gun may further include functional structures such as the gun handle, a trigger, the control module, and a power module.

Please refer to FIG. 17 through FIG. 19. The spraying rod assembly includes the gun barrel 21, the gun head assembly 20 and the outer housing 22.

Specifically, the gun barrel 21 is connected between the gun head assembly 20 and the gun handle as a delivery passage for the cleaning liquid. In a specific embodiment, a water passage connected with the gun barrel 21 may be arranged inside the gun handle, for example, and the water passage is communicated with a water source through a pipeline outside the spray gun.

Please refer to FIG. 17 through FIG. 19. The gun head assembly 20 is located at the front end of the gun barrel 21, and coaxially arranged with the gun barrel 21, the plurality of spray nozzles 234 is arranged at the front end of the gun head assembly 20, the spray nozzles 234 are arranged at intervals along a circumferential direction of the gun head assembly 20, the flow passage is arranged in the gun head assembly 20, the flow passage is communicated with the gun barrel 21, the gun head assembly 20 includes an adjustment device, and the adjustment device is configured to enable each spray nozzle 234 to be alternately communicated with the flow passage. It may be understood that, the gun head assembly 20 is integrated with a plurality of different types of spray nozzles 234, which may cause the water to be sprayed outward in different forms to meet use requirements of different conditions. An axis of the gun head assembly 20 in the disclosure is arranged colinearly with an axis of the gun barrel 21, and water flow is guided to a position corresponding to the spray nozzle 234 through the eccentrically arranged second flow passage, thereby realizing a symmetrical design of the gun head assembly 20 relative to the gun barrel 21, and meeting different industrial styling requirements, and when switching the spray nozzle 234, the adjustment device can be rotated along the axis of the gun barrel 21, which enables an adjustment to be more convenient.

Please refer to FIG. 17 through FIG. 19. The outer housing 22 serves as a surface decoration component of the gun barrel 21, and is detachably installed on an outer side of the gun barrel 21. In a specific embodiment, the outer housing 22 may be, for example, a two-half structure, and with corresponding buckles 2222 arranged between the two halves of the outer housings 22, a quick positioning may be achieved. The two halves of the outer housings 22 are connected by screws, and a sealing gasket is arranged between the two halves of the outer housings 22 to form a relatively closed space inside the outer housing 22.

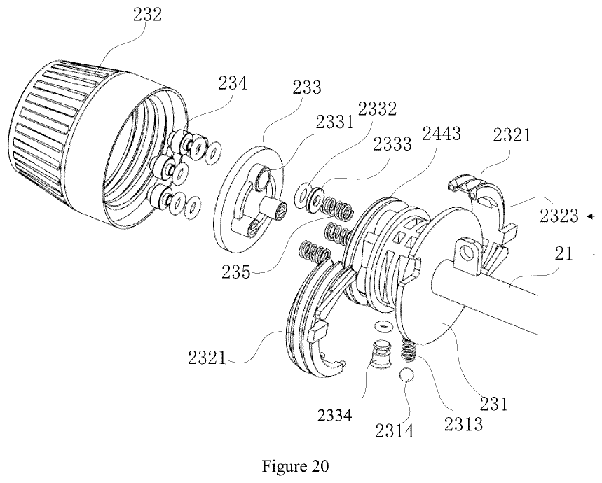

Please refer to FIG. 20, FIG. 12 through FIG. 14. The gun head assembly 20 includes the fixing component 231 and the spraying head housing 232. The first flow passage 2311 is formed in a center of the fixing component 231 along the axial direction, and the second flow passage 2312 is formed at a position off the center of the fixing component 231. The second flow passage 2312 is communicated with the first flow passage 2311. The first flow passage 2311 passes through the rear end of the fixing component 231, and the second flow passage 2312 passes through the front end of the fixing component 231. The spraying head housing 232 is coaxially arranged with the fixing component 231 and the spraying head housing 232 and the fixing component 231 is rotatably connected with each other. The spraying head housing 232 at least coves the front end of the fixing component 231, and the plurality of spray nozzles 234 is arranged on the housing wall of the spraying head housing 232 opposite to the front end of the fixing component 231. Each of the spray nozzles 234 is arranged at intervals along the circumferential direction of the first flow passage 2311, and when the spraying head housing 232 rotates relative to the fixing component 231, each spray nozzle 234 is alternately communicated with the second flow passage 2312.

In a specific embodiment, the first flow passage 2311 is the blind hole formed along the center of the fixing component 231, and the second flow passage 2312 is another blind hole eccentrically arranged relative to the first flow passage 2311. The two blind holes may be communicated with each other through the radial hole, for example. For ease of manufacturing, the radial hole may, for example, penetrate a side wall of the fixing component 231, and then a plug 2334 is arranged at an opening of the radial hole.

In a specific embodiment, the fixing component 231 may be integrally formed with the gun barrel 21, or it may be separately processed and assembled into one, for example, the fixing component 231 is connected with the gun barrel 21 by the threaded connection.

Please refer to FIG. 20, FIG. 12 through FIG. 14. In a specific embodiment, a first sealing ring 2442 is arranged between each spray nozzle 234 and the floating plate 233 to further prevent leakage.

Please refer to FIG. 20, FIG. 12 through FIG. 14. A protruding ring 2331 protruding toward the second flow passage 2312 is arranged at a position on the floating plate 233 corresponding to the through hole, and the protruding ring 2331 is inserted into the second flow passage 2312 and fits against an inner wall of the second flow passage 2312. It may be understood that, the protruding ring 2331 can isolate a space of the second flow passage 2312 from other spaces between the spraying head housing 232 and the fixing component 231. Meanwhile, the protruding ring 2331 can limit the floating plate 233 to prevent the floating plate 233 from being deflected.

Please refer to FIG. 20, FIG. 12 through FIG. 14. In a specific embodiment of the disclosure, a sinking groove is arranged at a front end of the second flow passage 2312, the protruding ring 2331 is inserted into the sinking groove, a gasket 2333 is arranged between the protruding ring 2331 and the sinking groove, a second sealing ring 2332 is arranged between the protruding ring 2331 and the gasket 2333, the first elastic unit 235 is a compression spring, the compression spring is installed in the second flow passage 2312, and a front end of the compression spring abuts against the gasket 2333. This embodiment strengthens a sealing of the second flow passage 2312 to further prevent leakage. It may be understood that, in order to enable the floating plate 233 to be more evenly stressed, in a specific embodiment, there may be a plurality of compression springs, and the plurality of compression springs are evenly arranged at intervals along a circumferential direction of the floating plate 233.

In summary, the axis of the gun head assembly 20 in the disclosure is arranged colinearly with the axis of the gun barrel 21, and the water flow is guided to the position corresponding to the spray nozzle 234 through the eccentrically arranged second flow passage, thereby realizing the symmetrical design of the gun head assembly 20 relative to the gun barrel 21, and meeting the different industrial styling requirements, and when switching the spray nozzle 234, the adjustment device can be rotated along the axis of the gun barrel 21, which enables the adjustment to be more convenient.

Considering that the cleaning machine needs to replace different cleaning accessories according to different cleaning conditions, cleaning accessories are generally installed at a front end of the high-pressure water gun of the cleaning machine. In the conventional art, when the cleaning accessory is connected with the high-pressure water gun of the cleaning machine, an assembly gap is often generated. An existence of the assembly gap will cause the cleaning accessory and the high-pressure water gun to be loosely connected with each other, which is prone to shaking. In addition, there is usually an obvious discontinuity or gap at the appearance connection between the cleaning accessory and the high-pressure water gun, which affects the appearance of the machine. The disclosure further provides a connecting device and the spray gun that can reduce the assembly gap.

Please refer to FIG. 5 through FIG. 9 and FIG. 21 through FIG. 22. The following is a detailed description of the connecting device provided by the disclosure in conjunction with the spray gun. It may be understood that the disclosure does not limit a specific type of the spray gun. The spray gun may be, for example, a lithium battery water gun, a high-pressure water gun, etc. As long as it is a cleaning tool with the detachable cleaning accessories, it is suitable for the connecting device provided by the disclosure.

Please refer to FIG. 5 through FIG. 9 and FIG. 21 through FIG. 22. The disclosure provides the spray gun, and the spray gun includes the gun body assembly 10 and the gun head assembly 20. The gun body assembly 20 includes the first connecting part. The gun head assembly 20 includes the second connecting part. The gun body assembly 10 is detachably connected with the gun head assembly 20 through the first connecting part and the second connecting part. In an embodiment, the second connecting part is plug-in fitted with the first connecting part. It may be understood that, the gun body assembly 10, as the main part of the spray gun, should be provided with necessary control elements. The control elements mentioned here may be mechanical control elements, such as triggers, handles, etc., or electronic control elements, such as electric control valves, control buttons, etc. In addition to these necessary control elements, the gun body assembly 10 may also include other hardware structures such as battery modules, display modules, control circuit boards, etc., so as to further improve functions of the spray gun. The gun head assembly 20 in the disclosure, which means the cleaning accessory mentioned above, refers to the part used to guide the water flow to be ejected, for example, it may include a water tube and the spraying head. A reason why the cleaning accessories are frequently replaced is that different types of spraying heads need to be replaced according to different usage requirements. Of course, some spraying heads themselves integrate multiple spraying types, but it should be noted that, through replacing the cleaning accessories, the function of the spray gun can be further expanded.

Please refer to FIG. 5 through FIG. 9 and FIG. 21 through FIG. 22. In this embodiment, the first connecting part includes the first limiting part and a first tube 144, the second connecting part includes the second limiting part and the gun barrel 21. When the first connecting part and the second connecting part are plugged into the preset position, the first tube 144 is fluidically communicated with the gun barrel 21. It may be understood that, the first tube 144 refers to a tube preset in the gun body assembly 10, which is generally communicated with a water source through an external pipeline. The gun barrel 21 refers to a tube preset in the gun head assembly 20, which means a tube connected with the spraying head. In some embodiments, the first tube 144 and the gun barrel 21 may be, for example, independent tubes, which are installed in the gun body assembly 10 and the gun head assembly 20 in a certain arrangement. In other embodiments, the first tube 144 and the gun barrel 21, for example, may also be integrated with other structures of the gun body assembly 10 or the gun head assembly 20. When these tubes are integrated with other structural components, they may be integrally processed and molded with these structural components. For example, when these structural components are made of plastic, the tubes may be integrally injection molded with these structural components.

Please refer to FIG. 5 through FIG. 9 and FIG. 21 through FIG. 22. When the first connecting part and the second connecting part are plugged into a preset position, the second limiting part is capable of forming a limiting match with the first connecting part, to keep the first connecting part and the second connecting part in the preset position. The elastic element 1011 is configured to apply an elastic force to the first connecting part and the second connecting part so as to cause the first connecting part and the second connecting part to be separated from each other when the first connecting part and the second connecting part are plugged into the preset position. It may be understood that, the elastic element 1011 of the disclosure causes the first connecting part and the second connecting part to have a tendency to be separated from each other, while the first limiting part and the second limiting part can prevent a separation of the first connecting part and the second connecting part. Therefore, there will always be a certain internal stress between the first connecting part and the second connecting part, and this internal stress may enable the two components fit as closely as possible, reduce the error caused by assembly, and prevent looseness between the gun head assembly 20 and the gun body assembly 10.

Please refer to FIG. 5 through FIG. 9 and FIG. 21 through FIG. 22. In a further embodiment of the disclosure, the connecting device further includes the floating ring 101, the floating ring 101 is movably connected with the first connecting part, a moving direction of the floating ring 101 is parallel to a plug-in direction of the first connecting part and the second connecting part, the first connecting part has an annular housing wall, an outer wall of the floating ring 101 is in contact with an inner wall of the annular housing wall, and the elastic element 1011 acts on the floating ring 101. When the first connecting part and the second connecting part are plugged into the preset position, and an elastic force of the elastic element 1011 is capable of driving an end face of the floating ring 101 to contact an end face of the second connecting part. It may be understood that, the floating ring 101 can eliminate cracks on a surface of a connecting part between the gun body assembly 10 and the gun head assembly 20. As a floating part, the floating ring 101 can always maintain a fit with the first connecting part and the second connecting part, which is equivalent to filling a gap between the first connecting part and the second connecting part, ensuring that the connecting part has a complete and continuous appearance shape, thereby improving an appearance quality of the product.

Please refer to FIG. 5 through FIG. 9 and FIG. 21 through FIG. 22. The first limiting part includes the limiting hole 141 with the non-circular cross-section, the second limiting part includes an inserting rod, and the limiting head 211 arranged at the end part of the inserting rod and matched with a contour of the cross-section of the limiting hole. The third notch 142 is arranged on the hole wall of the limiting hole 141. When the first connecting part and the second connecting part are plugged into the preset position, the limiting head 211 is aligned with the third notch 142, and at this time, the limiting head 211 is rotated to enable a contour of a cross-section of the limiting head 211 to be misaligned with the contour of the cross-section of the limiting hole 141, so as to block the limiting head 211 in the third notch 142. In this embodiment, the limiting hole 141 is a roughly flat structure. It is understandable that the limiting hole 141 may also be other non-circular structures, such as a triangular hole or a square hole. Accordingly, the limiting head 211 needs to be set to a same shape as the limiting hole 141. When the limiting head 211 rotates relative to the limiting hole 141, the limiting head 211 and the limiting hole 141 will be misaligned, and an outer protruding rotating pin of the limiting head 211 will sink into the third notch 142 to form a blockage.

Please refer to FIG. 5 through FIG. 9 and FIG. 21 through FIG. 22. In this embodiment, the inserting rod includes a partial section of an end part of the gun barrel 21 to ensure that the tube is coaxial with the limiting head 211 and prevent the gun barrel 21 and the first tube 144 from being misaligned during a rotation of the limiting head 211.

Please refer to FIG. 5 through FIG. 9 and FIG. 21 through FIG. 22. The first connecting part includes a casing 110, a clamping hood 120 and a core body 140. The casing 110 has a cylindrical part. The clamping hood 120 is sleeved on an outer side of the cylindrical part, and the core body 140 is detachably installed in the cylindrical part. The floating ring is 101 located between the core body 140 and the casing 110 and/or the clamping hood 120. A protruding block 143 is arranged on an outer wall of the core body 140, the elastic element 1011 is a compression spring, a first end of the compression spring abuts against the first protruding block 143, and a second end of the compression spring abuts against the floating ring 101. It may be understood that, the casing 110 is the outer housing of the gun body assembly 10, and the clamping hood 120 can ensure an integrity and continuity of an appearance of the connecting part. In this embodiment, a partial section of the first tube 144 and the first limiting part are formed on the core body 140. It may be understood that, the core body 140 is detachably connected, which realizes a modular design of the connecting device and facilitates an assembly and replacement of components.

Please refer to FIG. 9. The second connecting part includes an outer housing 22 covering an outside of the gun barrel 21, a side wall of one end of the outer housing 22 close to the first connecting part is flush with the outer wall of the floating ring 101, and when the first connecting part and the second connecting part are plugged into the preset position, the end face of the floating ring 101 contacts an end face of the outer housing 22. It may be understood that, in this embodiment, the outer housing 22 is arranged at an outside of the gun barrel 21.

In summary, the elastic element 1011 of the disclosure causes the first connecting part and the second connecting part to have the tendency to be separated from each other, while the first limiting part and the second limiting part can prevent the separation of the first connecting part and the second connecting part. Therefore, there will always be the certain internal stress between the first connecting part and the second connecting part, and this internal stress may enable the two components fit as closely as possible, reduce the error caused by assembly, and prevent looseness between the gun head assembly 20 and the gun body assembly 10. The floating ring 101 can eliminate cracks on the surface of the connecting part between the gun body assembly 10 and the gun head assembly 20. As the floating part, the floating ring 101 can always maintain the fit with the first connecting part and the second connecting part, which is equivalent to filling the gap between the first connecting part and the second connecting part, ensuring that the connecting part has the complete and continuous appearance shape, thereby improving an appearance quality of the product.

Considering that when the spray gun sprays water, some cleaning auxiliary agent is often necessary to be added at the same time, such as soap solution, the cleaning auxiliary agent is stored in a container and communicated with the water outlet tube of the water gun through a pipeline. When the water flows at a high speed, the cleaning auxiliary agent can be sucked from the container into the water outlet tube through negative pressure and mixed with the water. At present, the soap dispensers on the market are all vertically installed on the gun barrel, which results in a relatively simple overall style of the product, restricts the shape design of the product, and the assembly process of the conventional soap dispensers is cumbersome and inconvenient to replace. One or more embodiments of the disclosure further provide an auxiliary agent container mounting structure for the spray gun which can be installed horizontally and has a simple and efficient assembly process.

Please refer to FIG. 8. FIG. 8 is a partial perspective view of the spray gun. A gun head part of the spray gun is shown in the figure. It may be understood that, in addition to a structure shown in the figure, the spray gun should further include other necessary components such as the gun handle, a water supply tube, the control module, etc. A specific form of the spray gun is not limited. For example, it may be a mechanical spray gun, a lithium battery spray gun or a plug-in spray gun.

Please refer to FIG. 8 through FIG. 10 and FIG. 22 through FIG. 25. In a specific embodiment, the auxiliary agent container mounting structure of the spray gun includes a first port 214, a second port 2423, the first connecting part 221 and the second connecting part 241. It may be understood that, the first port 214 and the second port 2423 of the disclosure specifically refer to tube ports, which are used to achieve fluid communication.

Please refer to FIG. 8 through FIG. 10 and FIG. 22 through FIG. 25. The first port 214 is formed on an outer side of the gun head assembly 20 of the spray gun, and the first port 214 is communicated with the flow passage in the gun head assembly 20. In this embodiment, the first port 214 is arranged toward the front end of the gun head assembly 20. It may be understood that, the flow passage in the gun head assembly 20 refers to the first flow passage of the spray gun. A front end of the first flow passage is connected with the gun head assembly 20 of the spray gun, and a rear end of the first flow passage is connected with the water source through an external pipeline. According to Bernoulli's principle, when the water flows at a high speed in the first flow passage, it will cause the first port 214 to generate the negative pressure, so that when the auxiliary agent container is communicated with the first port 214, the cleaning auxiliary agent in the auxiliary agent container can be sucked into the first flow passage, and the cleaning auxiliary agent is mixed with the water flow and then sprayed out from the gun head assembly 20.

Please refer to FIG. 9 and FIG. 11. The second port 2423 is formed on an outer side of the auxiliary agent container 24 and communicated with a liquid storage space inside the auxiliary agent container 24. When the auxiliary agent container 24 is connected with the gun head assembly 20 in a horizontal state, the second port 2423 is located at a rear end of the auxiliary agent container 24. When installing the auxiliary agent container 24, the auxiliary agent container 24 is first placed close to a bottom of the gun head assembly 20 to align the second port 2423 with the first port 214, and then insert the second port 2423 into the first port 214 from front to back. It may be understood that, in this embodiment, the second port 2423 is an outwardly protruding short tube, and the first port 214 is an inwardly concave inserting groove. In other alternative embodiments, specific forms of the first port 214 and the second port 2423 may be interchanged, for example, the first port 214 is set as an outwardly protruding short tube, and the second port 2423 is set as an inwardly concave inserting groove.

Please refer to FIG. 8 through FIG. 10 and FIG. 22 through FIG. 25. The first connecting part 221 is formed on an outer wall of the gun head assembly 20. In a specific embodiment, considering that the gun head assembly 20 is placed horizontally, the first connecting part 221 is located at the lower end of the gun head assembly 20, and the auxiliary agent container 24 is installed below the gun head assembly 20. It may be understood that this installation position is not the only one. For example, the first connecting part 221 may also be arranged on two sides or an upper end of the gun head assembly 20. Accordingly, the auxiliary agent container 24 will be placed on the two sides or above the gun barrel assembly. However, considering a convenience of operation, installing the auxiliary agent container 24 below the gun head assembly 20 is a better choice.

Please refer to FIG. 8 through FIG. 10 and FIG. 22 through FIG. 25. The second connecting part 241 is formed on an outer wall of the auxiliary agent container 24. Corresponding to a position of the first connecting part 221, in this embodiment, the second connecting part 241 is located at an upper end of the auxiliary agent container 24. Similarly, when the position of the first connecting part 221 changes, the second connecting part 241 may also change accordingly, for example, be arranged on the two sides or the lower end of the auxiliary agent container 24.

Please refer to FIG. 8 through FIG. 10 and FIG. 22 through FIG. 25. The first connecting part 221 and the second connecting part 241 are configured such that when the auxiliary agent container 24 moves along a front-rear direction of the gun head assembly 20 to connect the first port 214 with the second port 2423, the first connecting part 221 and the second connecting part 241 are capable of being clamped with each other to fix the auxiliary agent container 24 to the outer wall of the gun head assembly 20. It may be understood that, the first connecting part 221 and the second connecting part 241 are assembled in a sliding manner. When the first port 214 is connected with the second port 2423, the second connecting part 241 can be engaged with the first connecting part 221 in the sliding manner to achieve a fixation between the auxiliary agent container 24 and the gun head assembly 20.

The disclosure places the auxiliary agent container 24 horizontally below the assembly of the gun barrel 241, and the auxiliary agent container 24 is connected with the outer housing of the gun head assembly 20 through the first connecting part 221 and the second connecting part 241. The assembly direction of the auxiliary agent container 24 is toward the user. The user only needs to hold the gun handle with one hand and complete assembly operation of the auxiliary agent container with the other hand, which enables the operation to be simpler and more labor-saving.

Please refer to FIG. 12 through FIG. 15 and FIG. 22 through FIG. 25. In a specific embodiment of the disclosure, the first connecting part 221 includes a sliding block 2125, and the second connecting part 241 includes a sliding groove 2441. Wings 2152 are arranged on two sides of the sliding block 2151 and protrude perpendicularly to a length direction of the gun head assembly 20, a strip groove 2442 matching the wings 2152 is arranged on a side wall of the sliding groove 2441, a first notch 2443 is arranged at a notch port of the sliding groove 2441, the first notch 2443 penetrates from a notch port of the sliding groove 2441 to the strip groove 2442, so as to insert the wing 2152 into the strip groove 2442 through the first notch 2443. It may be understood that, a configuration of the sliding block 2151 and the sliding groove 2441 is not unique, and their positions may be interchanged. For example, the first connecting part 221 may be configured as the sliding groove 2441, and the second connecting part 241 may be configured as the sliding block 2151.

In this embodiment, a specific assembly process of the auxiliary agent container 24 and the gun head assembly 20 is as follows: first, the first notch 2443 at the upper end of the auxiliary agent container 24 is aligned with the sliding block 2151 and the wing 2152 at the lower end of the gun head assembly 20, and then the auxiliary agent container 24 is fitted to the lower end of the gun head assembly 20. At this time, the wing 2152 may be inserted into the sliding groove 2441 through the first notch 2443 and be flush with the strip groove 2442. At the same time, the second port 2423 is aligned with the first port 214, and then the auxiliary agent container 24 is slid forward so that the wing 2152 is inserted into the strip groove 2442 to achieve the fixation between the auxiliary agent container 24 and the gun head assembly 20. At the same time, the second port 2423 can be inserted into the first port 214 to achieve a communication between the two.

Please refer to FIG. 22 through FIG. 25. A first restrict part 2153 is arranged on the wing 2152 or the sliding block 2151, and a second restrict part 2444 is arranged on an inner wall of the sliding groove 2441 or the strip groove 2442. The first restrict part 2153 is a first protruding part with a smooth surface, and the second restrict part 2444 is a first concave part. When the first port 214 is connected with the second port 2423, the first protruding part is clamped with the first concave part. It may be understood that, positions of the first protruding part and the first concave part are interchangeable. In this embodiment, the gun head assembly 20 and the auxiliary agent container 24 are both made of a material having a certain elasticity, such as plastic. Therefore, the first protruding part has a certain deformation ability and will not interfere with a sliding of the sliding block 2151 in the sliding groove 2441. When the first protruding part is aligned with the first concave part, the first protruding part will bounce into the first concave part, thereby forming a certain holding force to prevent the sliding block 2151 from falling off the sliding groove 2441.

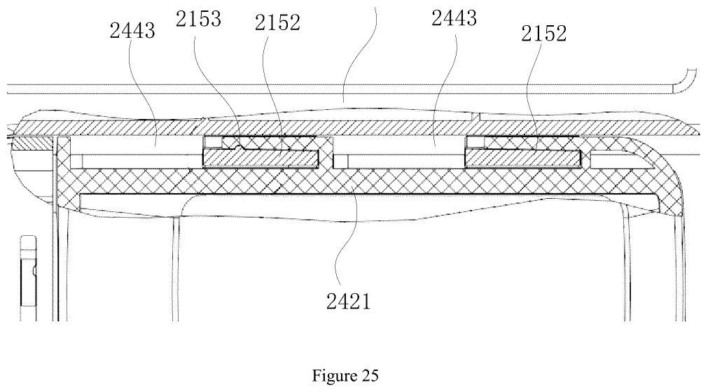

Please refer to FIG. 24 and FIG. 25. In a specific embodiment of the disclosure, the auxiliary agent container 24 includes a container body 2421 and a side cover 2422, a bottle mouth 2411 is formed on the container body 2421, the side cover 2422 is detachably installed on the bottle mouth 2411, and the second port 2423 is located on the side cover 2422. The container body 2421 and the side cover 2422 have a quick disassembly structure. In an embodiment, a second protruding block 2412 is arranged on an outer wall of the bottle mouth 2411, an arc groove 24221 matched with the second protruding block 2412 is arranged on an inner wall of the side cover 2422, a second notch 24222 is arranged at an end part of the side cover 2422, and the second notch 24222 penetrates into the arc groove 24221 to enable the second protruding block 2412 to be inserted into the arc groove 24221 through the second notch 24222. A specific assembly process of the container body 2421 and the side cover 2422 is that: first the second protruding block 2412 is aligned with the second notch 24222, and then the bottle mouth 2411 is inserted into the side cover 2422. When the second protruding block 2412 is flush with the arc groove 24221, the side cover 2422 or the container body 2421 is rotated so that the second protruding block 2412 is restricted in the arc groove 24221.

Please refer to FIG. 24. A second protruding part 24223 with a smooth surface is arranged on an inner wall of the arc groove 24221, a second concave part 2413 is arranged on the second protruding block 2412, and when the second protruding block 2412 is inserted into the arc groove 24221 and rotated by a preset angle, and the second protruding part 24223 is clamped with the second concave part 2413. Similarly, positions of the second protruding part 24223 and the second concave part 2413 may also be interchanged. When the second protruding part 24223 and the second concave part 2413 are clamped, they can provide a certain holding force between the container body 2421 and the side cover 2422 to prevent loosening.

Please refer to FIG. 11. An inner end of the second port 2423 is provided with a pipette 242 extending into an interior of the auxiliary agent container 24. The pipette 242 can extend to a bottom of the container body 2421, ensuring that each added cleaning auxiliary agent can be fully utilized.

Please refer to FIG. 11. A fourth sealing ring 245 is arranged between the first port 214 and the second port 2423, and a fifth sealing ring 246 is arranged between the container body 2421 and the side cover 2422 to prevent a leakage of the cleaning auxiliary agent.

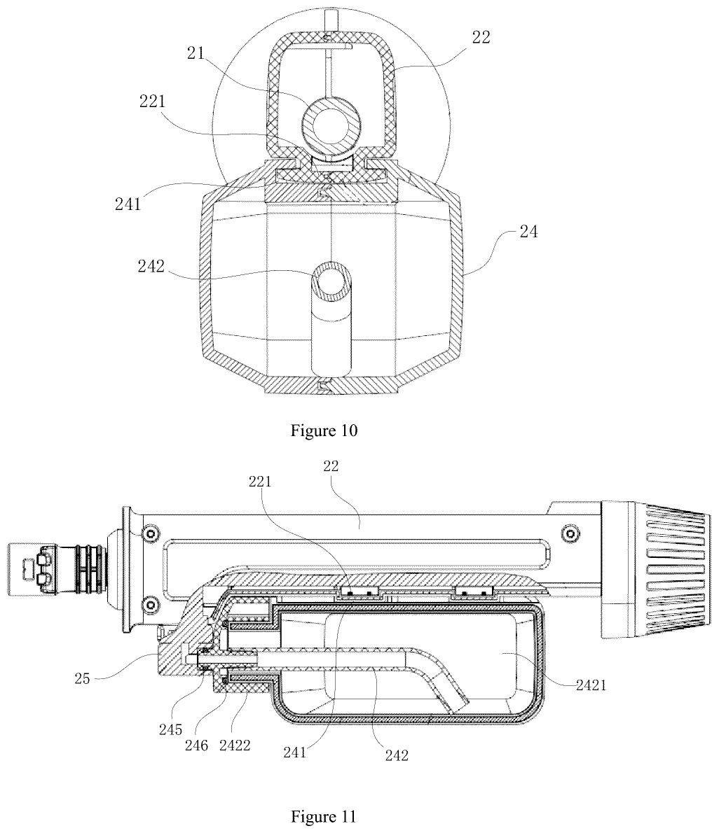

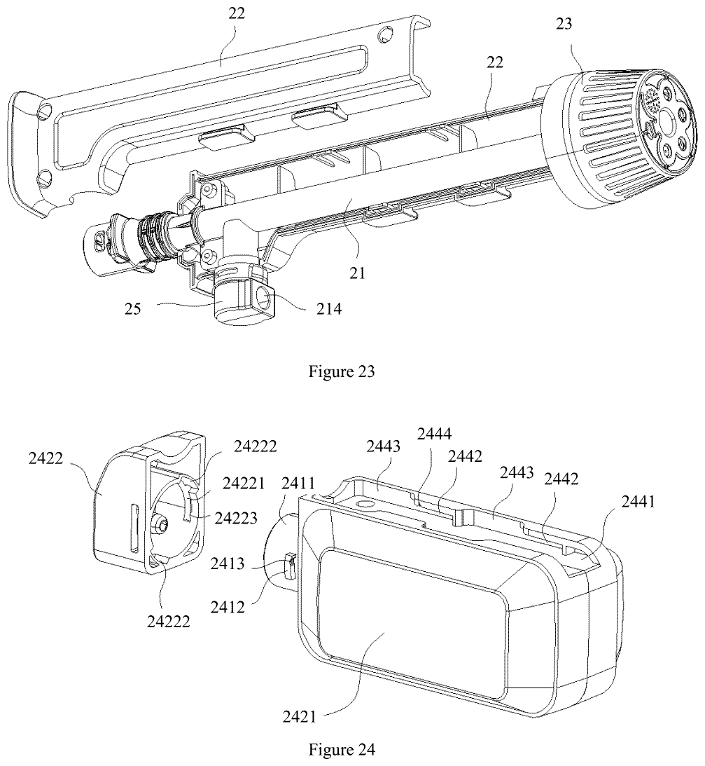

Please refer to FIG. 10 and FIG. 23. The gun head assembly 20 includes the gun barrel 21 and the outer housing 22, the outer housing 22 is installed on an outer side of the gun barrel 21, the right-angle tube 25 is connected with the gun barrel 21, the first end of the right-angle tube 25 is communicated with the gun barrel 21, and the second end of the right-angle tube 25 passes through an outer side of the outer housing 22 to form the first port 214. The gun barrel 21 and the outer housing 22 can be processed separately, so that the gun barrel 21 can meet pressure requirements, and at the same time the outer housing 22 can have a relatively complex structural design.

In summary, the disclosure places the auxiliary agent container 24 horizontally under the gun head assembly 20, and connects the auxiliary agent container 24 with an outer housing 22 of the gun head assembly 20 through the first connecting part and the second connecting part. The assembly direction of the auxiliary agent container is toward the user. The user only needs to hold the gun handle with one hand and complete assembly operation of the auxiliary agent container 24 with the other hand, which enables the operation to be simpler and more labor-saving. The disclosure arranges a series of limiting structures and sealing structures to ensure that the auxiliary agent container 24 is tightly connected with the gun head assembly 20 to avoid a leakage of cleaning auxiliary agent.

Considering that during an operation of the lithium battery cleaning machine, since the operating power is relatively large while ensuring the pressure and flow, the battery capacity is limited, and the use time is relatively short. However, in actual use, high power is not required all the time, and higher pressure is only required when cleaning stubborn stains. However, the spray guns in the conventional art lack information interaction functions, and users cannot obtain information such as the power information, operation state and faults of the spray guns, resulting in an inability to reasonably configure the operating power of the spray guns according to actual usage conditions, resulting in a decrease in the battery life of the spray guns, which affects cleaning efficiency. One or more embodiments of the disclosure provide a control method of the spray gun and the spray gun that can display a working state of the spray gun in real time to reasonably configure operating power.

Please refer to FIG. 1, FIG. 2 and FIG. 26 through FIG. 30. The technical solution of the disclosure is described in detail below in conjunction with a specific embodiment. FIG. 1 and FIG. 2 show a spray gun structure, which includes the gun body assembly 10 and the gun head assembly 20. The gun head assembly 20 is detachably connected with the gun body assembly 10, and the fluid driving element 15 and the control module 16 are arranged inside the gun body assembly 10, wherein the fluid driving element 15 is connected in series with the pipeline inside the spray gun to drive a movement of the fluid in the pipeline, and the display screen 12, a light module and a control switch are arranged on a surface of the gun body assembly 10. In a specific embodiment, the gun body assembly 10 is formed with a handle part 11, the battery pack compartment 30 is arranged at the lower end of the handle part 11, and a detachable battery pack is arranged in the battery pack compartment 30.

Please refer to FIG. 1 and FIG. 2. The display screen 12, the light module, the control switch, the fluid driving element 15, and the battery pack are electrically connected with the control module 16, respectively. In the present embodiment, the display screen 12 may be installed at the rear end of the gun body assembly 10, and the light module may include an annular light surrounding the display screen 12 and atmosphere lights 13 arranged on the two sides of the gun body assembly 10. It may be understood that, installation positions of the display screen 12 and the light module are not unique. For example, the display screen 12 and the light module may also be installed at other positions that are easy to identify according to the design requirements.

Please refer to FIG. 2. In this embodiment, the control switch includes the on-off switch 17 and the speed regulation switch 18. The on-off switch 17 may be arranged in the handle part 11, and the handle part 11 is provided with the trigger 19 for triggering the on-off switch 17. The speed regulation switch 18 may be arranged at the tail part of the gun body assembly 10 and in an area that can be touched by the thumb, so that the user can operate it with one hand.

Please refer to FIG. 1 and FIG. 2. It may be understood that, in order to further improve the function of the spray gun, the gun head assembly 20 may further include the auxiliary agent container 24 and the multifunctional gun head assembly 20. During operation, the spray gun can use negative pressure to suck soap liquid in the auxiliary agent container 24 into the flow passage, and the soap liquid is mixed with the high-pressure water flow and sprayed out from the multifunctional gun head assembly 20.

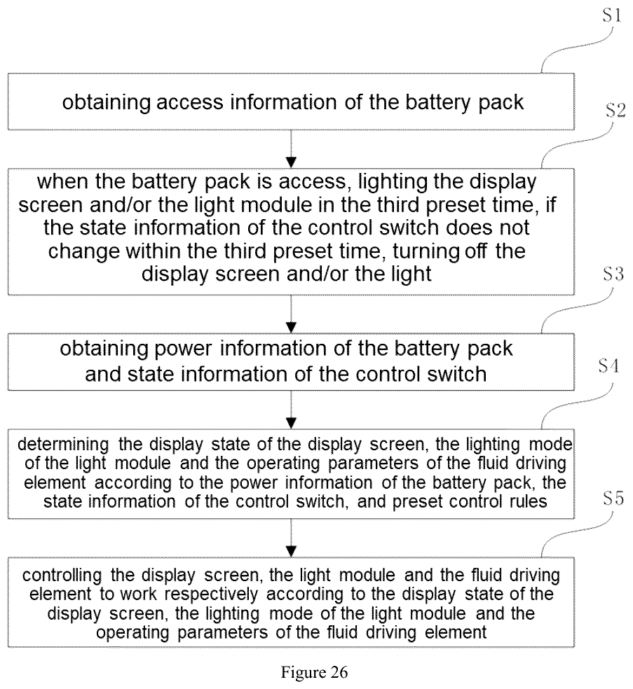

Please refer to FIG. 26 through FIG. 30. In a specific embodiment, a control method of the spray gun is as follows.

S1: Access information of the battery pack is obtained. It may be understood that, in addition to a necessary power supply port, a corresponding data transmission port may further be arranged between the battery pack and the spray gun, so that the control module 16 may obtain an access status and remaining power of the battery pack.

S2: When the battery pack is access, the display screen 12 and/or the light module is lit in a third preset time. If the state information of the control switch does not change within the third preset time, the display screen 12 and/or the light module is turned off. This process is used to prompt the user that the battery pack has been successfully connected with the spray gun. In a specific embodiment, when the battery pack is connected, the atmosphere light 13 flashes once and then is turned off, while the display screen 12 and the annular light are turned on. After 30 seconds, if there is no other operation, the display screen 12 and the annular light are turned off to save power.

S3: Power information of the battery pack and state information of the control switch are obtained. The state information of the control switch refers to a connection state of the control switch, such as a connected state or a disconnected state.

S4: A display state of the display screen 12, a lighting mode of the light module and operating parameters of the fluid driving element 15 are determined according to the power information of the battery pack, the state information of the control switch, and preset control rules. It is understandable that a preset control rule is a man-made rule, which may be designed according to common application conditions of the spray gun and general understanding habits of the users, and will be explained in conjunction with a specific embodiment below.

S5: The display screen 12, the light module and the fluid driving element 15 are controlled to work respectively according to the display state of the display screen 12, the lighting mode of the light module and the operating parameters of the fluid driving element 15.

It may be understood that the disclosure combines the power information of the battery with working state information of the water gun, generates visual prompt information based on this information, and displays it to the user in real time. The user can have a more intuitive understanding of the power, working state, etc. of the spray gun based on the visual information, which facilitates the user to reasonably allocate the operating power of the spray gun according to actual usage needs, improve an endurance of the spray gun, avoid waste of resources, and improve cleaning efficiency.

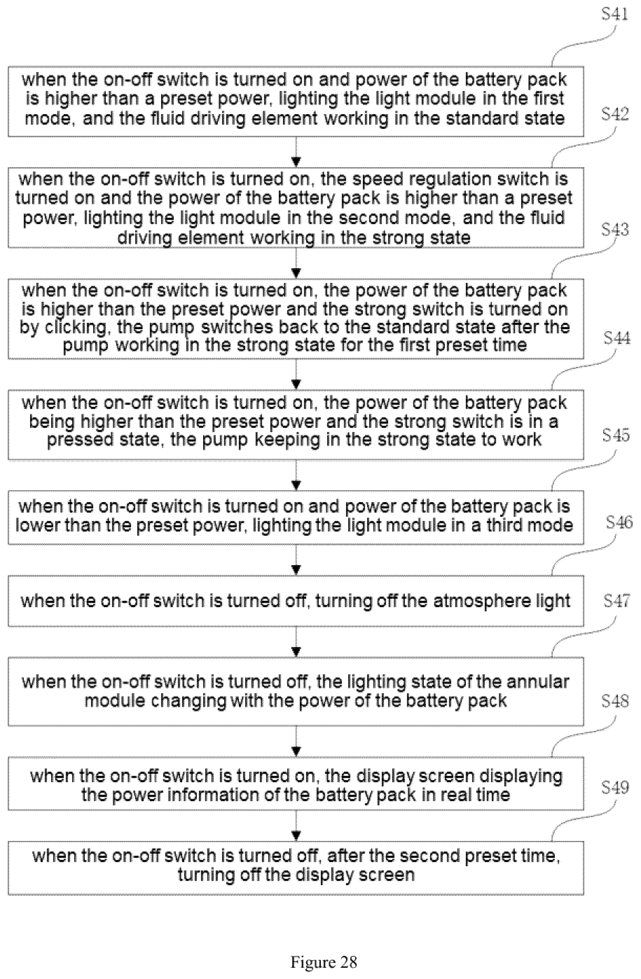

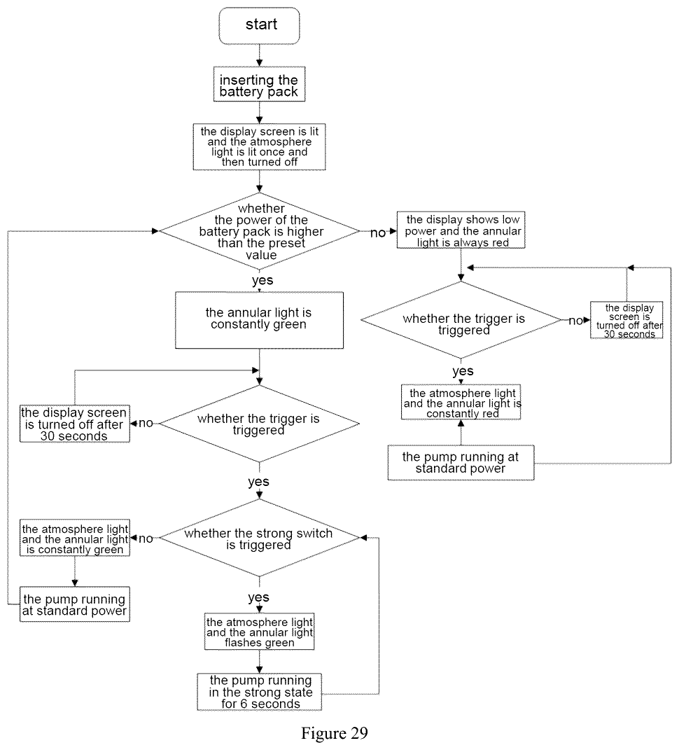

Please refer to FIG. 28 and FIG. 29. In a specific embodiment, S4 specifically includes an operation as follows.

S41: When the on-off switch 17 is turned on and power of the battery pack is higher than a preset power, the light module is lit in a first mode, and the fluid driving element 15 works in a standard state. In a specific embodiment, the preset power may be, for example, 15% of a fully charged state. The first mode may be, for example, the atmosphere light 13 and the annular light being constantly green, and the standard state means that the fluid driving element 15 operates at a lower power, such as 100 W, or the fluid driving element 15 operates at a lower water pressure, such as 1 Mpa. It should be noted that, the various parameters provided in the specific embodiments of the disclosure are not intended to limit the disclosure, but should be understood as a preferred arrangement.

S42: When the on-off switch 17 is turned on, the speed regulation switch 18 is turned on and the power of the battery pack is higher than a preset power, the light module is lit in a second mode, and the fluid driving element 15 works in a strong state. In a specific embodiment, the second mode may be, for example, the atmosphere light 13 and the annular light flashing green, and the strong state means that the fluid driving element 15 operates at a higher power, such as 350 w, or the fluid driving element 15 operates at a higher water pressure, such as 4 Mpa. It should be noted that, in a further embodiment, the speed regulation switch 18 is effective only when the power is higher than the preset power. When the power is lower than the preset power, the speed regulation switch 18 is pressed, and the system prioritizes improving a battery life and does not make any response.

S43: When the on-off switch 17 is turned on, the power of the battery pack is higher than the preset power and the speed regulation switch 18 is turned on by clicking, the fluid driving element 15 switches back to the standard state after the fluid driving element works in the strong state for the first preset time. In a specific embodiment, the first preset time may be, for example, 6 seconds.

S44: When the on-off switch 17 is turned on, the power of the battery pack is higher than the preset power and the speed regulation switch 18 is in a pressed state, the fluid driving element 15 keeps in the strong state to work.

S45: When the on-off switch 17 is turned on and power of the battery pack is lower than the preset power, the light module is lit in a third mode. In a specific embodiment, the third mode may be, for example, that the atmosphere light 13 and the annular light are constantly red.

S46: When the on-off switch 17 is turned off, the atmosphere light 13 is turned off.

S47: When the on-off switch is turned off and the power of the battery pack is higher than the preset power, the annular module is lit in a fourth mode. In a specific embodiment, the fourth mode may be, for example, that when the power of the battery pack is higher than the preset power, the annular light is constantly green, and when the power of the battery pack is lower than the preset power, the annular light is constantly red.

S48: When the on-off switch 17 is turned on, the display screen 12 displays the power information of the battery pack in real time. In a specific embodiment, the power information may be represented by a progress bar or numbers, for example.

S49: When the on-off switch 17 is turned off, after a second preset time, the display screen 12 is turned off. In a specific embodiment, the second preset time may be, for example, 30 seconds.

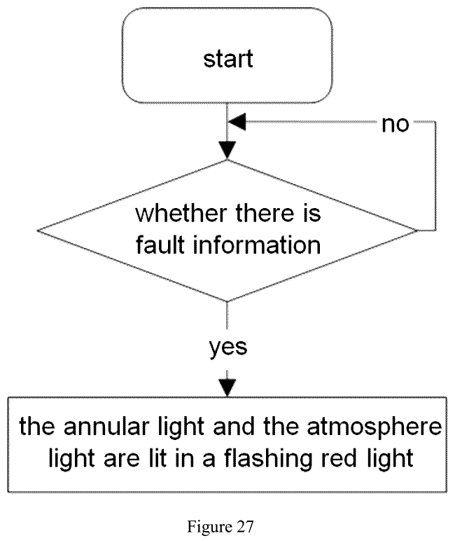

Please refer to FIG. 27. During operation, the spray gun of the disclosure may also obtain fault information of each module in real time, and send the fault information to the display screen 12 for display. At the same time, the light module may also issue a warning for the fault information, for example, the annular light and the atmosphere light 13 may be lit at the same time in a flashing red light. In a specific embodiment, the display screen 12 may, for example, display codes for different faults, such as using E1-E9 to represent different fault types, and these fault codes and their corresponding specific fault types may be recorded in a product manual, for example, to facilitate users to identify the fault type according to the code. In a specific embodiment, when a system failure occurs, the fault information is displayed first regardless of the current working state of the spray gun.

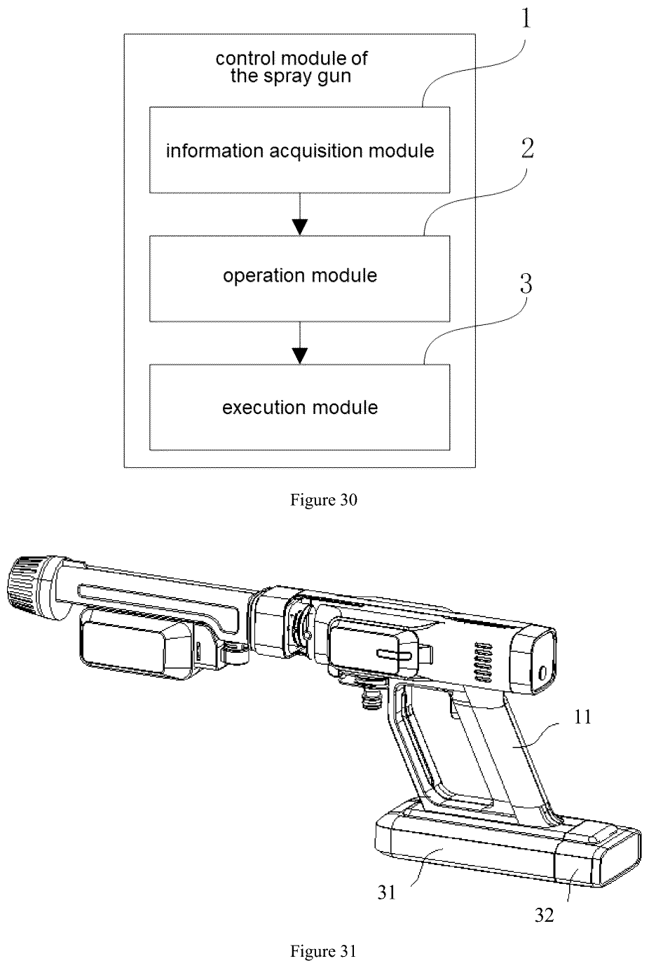

Please refer to FIG. 30. In a specific embodiment, the control module 16 may be integrated in a PCB control board, for example, and the control module 16 may include an information acquisition module 1, an operation module 2 and an execution module 3. The information acquisition module 1 is used to obtain the power information of the battery pack and the state information of the control switch. The operation module 2 is used to determine the display state of the display screen 12, the lighting mode of the light module and the operating parameters of the fluid driving element 15 according to the power information of the battery pack and the state information of the control switch, as well as preset control rules. The execution module 3 is used to control the display screen 12, the light module and the fluid driving element 15 to work respectively according to the display state of the display screen 12, the lighting mode of the light module and the operating parameters of the fluid driving element 15.

It should be noted that, an operation arrangement of the above methods is only for clear description. When implemented, they may be combined into one operation or some operations may be split and decomposed into multiple operations. As long as they contain a same logical relationship, they are all within a protection scope of this disclosure. Adding insignificant modifications to an algorithm or process or introducing insignificant designs without changing a core design of the algorithm and process are all within the protection scope of this disclosure.

The control module 16 of this embodiment is a device corresponding to the above control method, and functional modules in the control module 16 correspond to the corresponding operations in the control method respectively. The control module 16 of this embodiment may be implemented in coordination with the control method. Correspondingly, relevant technical details mentioned in the control module 16 of this embodiment may also be applied to the above control method.

It should be noted that, when actually implemented, the above-mentioned functional modules may be fully or partially integrated into one physical entity, or may be physically separated. And these modules may all be implemented in a form of software calling through processing elements, or all be also implemented in a form of hardware, or some modules may be further implemented in a form of software calling through processing elements, and some modules may be implemented in the form of hardware. In addition, all or part of these modules may be integrated together or implemented independently. The processing elements described here may be an integrated circuit having a signal processing capability. During implementation, part or all of the operations of the above method, or each of the above functional modules, may be completed by hardware integrated logic circuits in a processor element or by instructions in software form.

In summary, the disclosure combines the power information of the battery with working state information of the water gun, generates the visual prompt information based on this information, and displays it to the user in real time. The user can have the more intuitive understanding of the power, working state, etc. of the spray gun based on the visual information, which facilitates the user to reasonably allocate the operating power of the spray gun according to actual the usage needs, improve the endurance of the spray gun, avoid the waste of resources, and improve the cleaning efficiency.

Considering that conventional battery pack compartments are widely arranged in portable tools, the battery pack compartment is mainly used to fix and protect the battery pack. The battery pack is detachably installed in the battery pack compartment to facilitate the replacement of the battery pack, so the battery pack compartment is generally equipped with a detachable compartment cover. Most battery pack compartments and compartment covers are assembled by a buckle. However, the buckle assembly is limited by space and the buckle can be easily broken, causing the entire structure to fail. In addition, the locking force of the buckle is difficult to control. If the buckle is too tight, the disassembly and installation process will be more laborious. If the buckle is too loose, the compartment cover will become loose or even fall off. One or more embodiments of the disclosure provide the battery pack compartment and a cleaning tool that facilitates a disassembly and assembly of the battery pack.

Please refer to FIG. 31. The disclosure describes the technical solution of the disclosure in detail in conjunction with the spray gun. It may be understood that the battery pack compartment of the disclosure is not limited to use in spray guns, for example, it may also be applied to other portable tools such as electric screwdrivers.

Please refer to FIG. 31. The spray gun includes the handle part 11 and the battery pack compartment arranged at the lower end of the handle part 11. As a necessary functional unit, the spray gun should further include structures such as the gun barrel, the spraying head, and the water tube. The spray gun in this embodiment further includes electrical components such as the display screen and the control module. The battery pack is installed in the battery pack compartment for powering these electrical components.

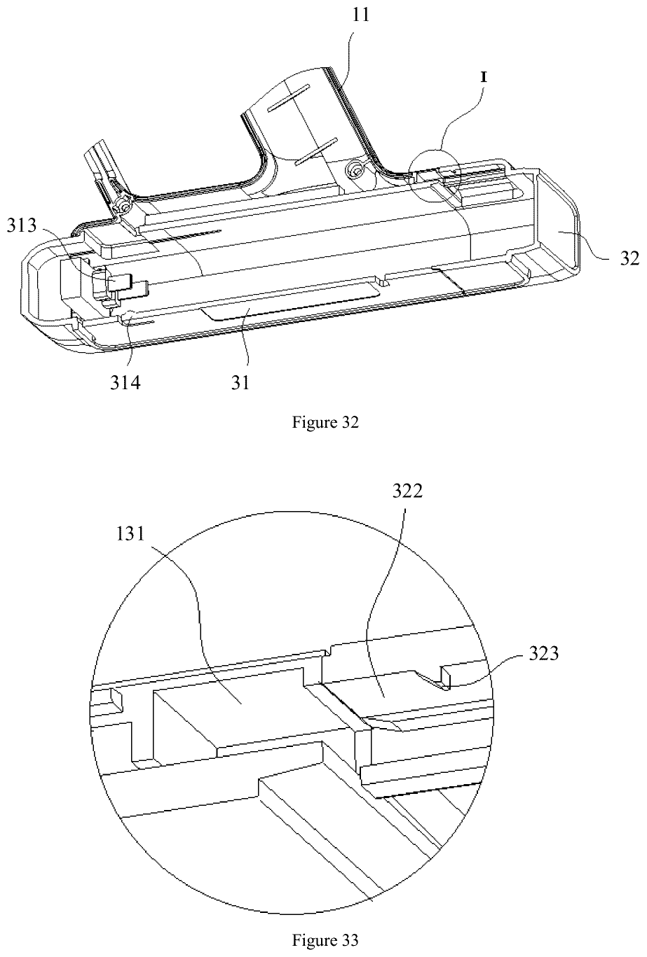

Please refer to FIG. 16, FIG. 32 through FIG. 35. The battery pack compartment is installed at a lower end of the handle part 11, and the battery pack compartment includes the body 31 and the compartment cover 32. The body 31 is fixedly connected with the handle part 11, and an edge of the body 31 is detachably connected with an edge of the compartment cover 32, so that the body 31 and the compartment cover 32 together enclose a space for accommodating the battery pack. At least one first magnetic unit 33 is arranged at the edge of the body 31, and at least one second magnetic unit 34 is arranged at the edge of the compartment cover 32. When the edge of the body 31 is connected with the edge of the compartment cover 32, the first magnetic unit 33 and the second magnetic unit 34 can be attracted to each other to keep the body 31 and the compartment cover 32 in a connected state. One of the first magnetic unit 33 and the second magnetic unit 34 is a permanent magnet, and the other one of the first magnetic unit 33 and the second magnetic unit 34 is a ferromagnetic material or a permanent magnet.

Please refer to FIG. 16, FIG. 32 through FIG. 35. In a specific embodiment of the disclosure, a mounting groove 131 to accommodate the first magnetic unit 33 is arranged on an outer wall at the edge of the body 31, a fourth notch 132 is formed on a side of the mounting groove 131 close to the edge of the body 31, and the second magnetic unit 34 is arranged to protrude from the edge of the compartment cover 32, so as to enable the second magnetic unit 34 to pass through the fourth notch 132 and engage with the first magnetic unit 33 in the mounting groove 131 when the body 31 is connected with the compartment cover 32. In this embodiment, the mounting groove 131 is formed at a bottom of the handle part 11. It may be understood that, the mounting groove 131, for example, may also be formed on an outer wall of the body 31. The mounting groove 131, for example, may be integrally injection molded with the handle part 11 or the body 31. In this embodiment, the first magnetic unit 33 is the permanent magnet, and the second magnetic unit 34 is an iron sheet.

Please refer to FIG. 16, FIG. 32 through FIG. 35. In a specific embodiment of the disclosure, an inserting groove 322 is arranged at the edge of the compartment cover 32, and the second magnetic unit 34 is inserted into the inserting groove 322. A limiting device is arranged between the second magnetic unit 34 and the inserting groove 322, and the limiting device is configured to enable the second magnetic unit 34 to remain in the inserting groove 322. Specifically, in this embodiment, the limiting device includes a wedge block 323 protruding from an inner wall of the inserting groove 322, and a second limiting groove 3211 arranged on the second magnetic unit 34. When the second magnetic unit 34 is inserted into the inserting groove 322, the wedge block 323 is clamped with the second limiting groove 3211.

Please refer to FIG. 16, FIG. 32 through FIG. 35. In a specific embodiment of the disclosure, a volume of the body 31 is smaller than a volume of the battery pack, so as to enable at least a part of the area to protrude to an outer side of the body 31 when the battery pack is inserted into the body 31, and an area protruding to the outer side of the body 31 is accommodated in the compartment cover 32. Advantages of this arrangement are that the battery pack may be used as a guiding structure when assembling the body 31 and the compartment cover 32. During assembly, it only needs to put the compartment cover 32 on the battery and then push the compartment cover 32 to accurately connect the compartment cover 32 with the body 31 and accurately engage the first magnetic unit 33 with the second magnetic unit 34, which enables an installation of the battery compartment cover to be easier and improves usage experience.

Please refer to FIG. 16, FIG. 32 through FIG. 35. In a specific embodiment of the disclosure, a third restrict part 312 is arranged at the edge of the body 31, and a fourth restrict part 324 is arranged at the edge of the compartment cover 32, and the third restrict part 312 and the fourth restrict part 324 are configured to limit a relative movement direction of the body 31 and the compartment cover 32 to a first direction in a process of connecting the body 31 with the compartment cover 32 or separating the body 31 and the compartment cover 32 from each other. The first direction is parallel to a direction of an attraction force between the first magnetic unit 33 and the second magnetic unit 34. In this embodiment, one of the third restrict part 312 and the fourth limiting part 324 is a second protruding flange, and the other one of the third restrict part 312 and the fourth restrict part 324 is a sinking groove that forms a plug-in fit with the second protruding flange. The third restrict part 312 and the fourth restrict part 324 are matched with each other to prevent a lateral displacement between the body 31 and the compartment cover 32.

Please refer to FIG. 16, FIG. 32 through FIG. 35. A wiring terminal 313 is arranged at one end of an interior of the body 31 away from the compartment cover 32, and the wiring terminal 313 is connected with a power module inside the spray gun through a wire.

Please refer to FIG. 16, FIG. 32 through FIG. 35. An elastic buckle 314 is formed on a side wall of the body 31, and the elastic buckle 314 is used to be clamped with a clamping groove arranged on a side wall of the battery pack to prevent the battery from loosening.

In summary, the disclosure adopts the magnetic attraction structure to realize the connection between the battery pack compartment and the compartment cover. There will be no problem of a buckle breakage, and assembly and disassembly are very easy. The battery pack is used as the guiding structure when assembling the body 31 and the compartment cover 32. During assembly, it only needs to put the compartment cover 32 on the battery and then push the compartment cover 32 to accurately connect the compartment cover 32 with the body 31 and accurately engage the first magnetic unit 33 with the second magnetic unit 34, which enables an installation of the battery compartment cover to be easier and improves usage experience. The third restrict part 312 and the fourth restrict part 324 are matched with each other to prevent a lateral displacement between the body 31 and the compartment cover 32.

The above embodiments only illustrate principles and effects of the disclosure, but are not intended to limit the disclosure. Anyone familiar with this technology may modify or change the above embodiments without departing from a scope of the disclosure. Therefore, all equivalent modifications or changes made by those with ordinary knowledge in the technical field without departing from the technical ideas disclosed in the disclosure shall still be covered by the claims of the disclosure.

In the description herein, many specific details are provided, such as examples of components and/or methods, to provide a complete understanding of the embodiments of the disclosure. However, those skilled in the art will recognize that the embodiments of the disclosure may be realized without one or more specific details or through other devices, systems, assemblies, methods, components, materials, parts, etc. In other cases, well-known structures, materials, or operations are not specifically shown or described in detail to avoid obscuring aspects of the embodiments of the disclosure.

In the description of this specification, a description with reference to the terms “this embodiment”, “embodiment”, “specific embodiment”, etc. means that a specific feature, structure, or characteristic described in connection with this embodiment or example is included in at least one embodiment, and not necessarily in all embodiments. Therefore, in this specification, schematic representations of the above terms in “this embodiment”, “embodiment”, “specific embodiment” do not necessarily refer to the same embodiment or example. Furthermore, the particular features, structures, materials or characteristics described may be combined in any suitable manner in any one or more embodiments or examples. It should be understood that other variants and modifications of the embodiments of the disclosure described and shown herein may be taught herein and will be deemed to be part of scope of the disclosure.

It should also be understood that one or more of the components shown in the drawings may also be implemented in a more separate or integrated manner, or may even be removed because it cannot be operated in some cases or may be provided because it is useful according to a particular application.

In addition, unless expressly indicated otherwise, any marking arrows in the drawings should be regarded only as exemplary instead of limiting. What's more, unless specified otherwise, the term “or” as used herein generally means “and/or.” In cases where the term is foreseen because it is unclear to provide separation or combination capabilities, the combination of components or operations will also be regarded as specified.

As used in the description herein and throughout the claims below, unless otherwise indicated, “a” and “the” include plural references. Similarly, as used in the description herein and throughout the claims below, unless otherwise indicated, “in the . . . ” includes “in the . . . ” and “on the . . . ”.

The above description of the illustrated embodiment of the disclosure (including content described in the abstract of the specification) is not intended to exhaustively enumerate or limit the disclosure to the precise form provided herein. Although specific embodiments of the disclosure and examples of the disclosure are described herein for illustrative purposes only, as those skilled in the art recognize and understand, various equivalent modifications are possible within the scope of the disclosure. As pointed out, these modifications may be made to the disclosure according to the above description of the embodiments of the disclosure, and these modifications will be within the scope of the disclosure.

This specification has generally described the system and method which are helpful in understanding the details of the disclosure. In addition, various specific details have been given to provide an overall understanding of the embodiments of the disclosure. However, those skilled in the relevant art will recognize that the embodiments of the disclosure may be realized without one or more specific details, or may be implemented through using other devices, systems, accessories, methods, assemblies, materials, parts, etc. In other cases, well-known structures, materials, and/or operations are not specifically shown or described in detail to avoid confusion in various aspects of the embodiments of the disclosure.

Therefore, although the disclosure has been described herein with reference to its specific embodiments, a freedom of modification, various changes and substitutions are also included in the above disclosure. And it should be understood that in some cases, without departing from the scope of the disclosure, some features of the disclosure will be adopted under the conditions without corresponding use of other features. Therefore, many modifications may be made to enable a specific environment or material to adapt the essential scope of the disclosure. The disclosure is not intended to limit the specific terms used in the claims and/or specific embodiments disclosed as the best embodiment for carrying out the disclosure, but the disclosure will include any and all embodiments and equivalents falling within the scope of the appended claims. Therefore, the scope of the disclosure will only be determined by the appended claims.

What is claimed is:

1. A spray gun, comprising:
a gun body;
a flow passage, the flow passage formed in the gun body, a first end of the flow passage passing through the gun body to form a water inlet of the spray gun on an outside of the gun body, and a second end of the flow passage communicated with a spraying head;
a fluid driving element, the fluid driving element installed in the gun body and configured to drive fluid in the flow passage;
a control module, the control module electrically coupled to the fluid driving element;
a visual interface module, the visual interface module installed on the gun body, exposed on a surface of the gun body, and electrically coupled to the control module;
a switch assembly, the switch assembly electrically connected with the control module and at least including an on-off switch and a speed regulation switch, and
a battery pack, the battery pack electrically connected with the control module;
wherein, the control module is configured to obtain power information of the battery pack and/or working state information of the fluid driving element, and display the power information of the battery pack and/or the working state information of the fluid driving element through the visual interface module.

2. The spray gun according to claim 1, wherein, the gun body comprises:
a gun body assembly, the gun body assembly enclosed by a housing, formed with a handle part, and the fluid driving element, the control module and the switch assembly installed on the gun body assembly;
a gun head assembly, the gun head assembly detachably installed on a front end of the gun body assembly, and a front end of the gun head assembly provided with the spraying head; and
a battery pack compartment, the battery pack compartment located at a lower end of the handle part, and the battery pack installed in the battery pack compartment;
wherein, the battery pack compartment comprises a body and a compartment cover, and the compartment cover and the body are respectively provided with magnetic units.

3. The spray gun according to claim 2, wherein, the visual interface module comprises a display screen and/or an atmosphere light, the display screen is installed at a rear end of the gun body assembly, the atmosphere light is installed on two sides of the gun body assembly, the speed regulation switch is installed in a position touchable by the thumb of a user when the user holds the handle, a clamping ring is provided at the rear end of the gun body assembly, the clamping ring is detachably connected with the gun body assembly, the display screen is accommodated in the clamping ring, a first protruding flange is arranged on an inner wall of the clamping ring, the first protruding flange abuts against an outer edge of the display screen to limit the display screen within the clamping ring, the gun head assembly comprises a gun barrel, an outer housing, the spraying head and an auxiliary agent container, the outer housing is configured to cover an outside of the gun barrel, the spraying head is connected with a front end of the gun barrel, the auxiliary agent container is installed on the outer housing and is communicated with the gun barrel through a pipeline.

4. The spray gun according to claim 3, wherein, a quick-connector is arranged between the gun barrel and the flow passage inside the gun body assembly, a floating ring is arranged on the gun body assembly or the gun head assembly, the floating ring is movably connected with the gun body assembly or the gun head assembly along an axis direction of the gun barrel, an elastic element is arranged between the floating ring and the gun body assembly or the gun head assembly, when the quick-connectors are connected with each other, the elastic element is compressed to cause the floating ring to press against an end face of the gun body assembly or against an end face of the gun head assembly; the spraying head is coaxially arranged with the gun barrel, the spraying head comprises a fixing component and a spraying head housing, the fixing component is fixedly connected with the gun barrel, a first flow passage coaxially arranged with an axis of the gun barrel and a second flow passage eccentrically arranged relative to the axis of the gun barrel are formed in the fixing component, the spraying head housing is rotatably connected with the fixing component, a plurality of spray nozzles are circumferentially arranged at a front end of the spraying head housing, and when the spraying head housing rotates relative to the fixing component, each of the spray nozzle is capable of being alternately communicated with the second flow passage.

5. The spray gun according to claim 4, wherein, a right-angle tube is communicated with the gun barrel, the right-angle tube passes through the outer housing and forms an auxiliary agent container connector parallel to the gun barrel on an outside of the outer housing, the auxiliary agent container is connected with the auxiliary agent container connector along a direction parallel to the gun barrel, a sliding clamping mechanism is arranged between the outer housing and the auxiliary agent container, the sliding clamping mechanism comprises a first connecting part fixed with the outer housing and a second connecting part fixed with the auxiliary agent container, a limiting protrusion is arranged on the first connecting part, and a limiting groove matched with the limiting protrusion is arranged on an inner wall of the second connecting part.

6. The spray gun according to claim 1, further comprising a display screen mounting structure, wherein, the display screen mounting structure comprises a gun body assembly, a clamping ring and a display screen, the gun body assembly serves as a covering component to cover a surface of the spray gun, the clamping ring is detachably connected with the gun body assembly, the display screen is installed on the clamping ring in a manner that a display surface of the display screen is capable of being exposed, a first limiting part is arranged on the gun body assembly, a second limiting part is arranged on the clamping ring, the first limiting part and the second limiting part are assembled so that when the clamping ring and the gun body assembly are in a connected state, the first limiting part and the second limiting part are capable of blocking each other to prevent the clamping ring from separating from the gun body assembly, and a through hole is formed in an area of the gun body assembly connected with the clamping ring, so that a mounting area of the display screen is communicated with an inner area of the gun body assembly.

7. The spray gun according to claim 6, wherein, at least one of the first limiting part and the second limiting part is assembled to be capable of deforming or displacing under an action of external force so as to release a mutual blocking state between the first limiting part and the second limiting part, the clamping ring is an annular structure, an annular plug-in part is formed on the gun body assembly, the plug-in part is plugged into an inner wall of the clamping ring; the second limiting part comprises a second wedge part arranged on the inner wall of the clamping ring, the first limiting part comprises a first wedge part arranged on an outer wall of the plug-in part, notches are formed on the plug-in parts on two sides of the first limiting part so that an area where the first limiting part is located forms a cantilever structure, one of the clamping ring and the plug-in part is provided with a positioning pin, and the other one of the clamping ring and the plug-in part is provided with a positioning groove plug-in fitted with the positioning pin, an end of the clamping ring away from the gun body assembly is provided with a first protruding flange protruding inward, an edge of the display screen is blocked by the first protruding flange to limit the display screen within the clamping ring, the clamping ring is connected with one end of the gun body assembly that forms a tail part of the spray gun, a step part is formed between the plug-in part and the gun body assembly, and a thickness of the step part is consistent with a thickness of the clamping ring, so that when the clamping ring is connected with the gun body assembly, a surface of the clamping ring is flush with a surface of the gun body assembly.

8. The spray gun according to claim 2, wherein, the gun head assembly comprises:
a fixing component, a first flow passage formed in a center of the fixing component along an axial direction, a second flow passage formed at a position off the center of the fixing component, the second flow passage communicated with the first flow passage, the first flow passage passing through a rear end of the fixing component, and the second flow passage passing through a front end of the fixing component; and
a spraying head housing, the spraying head housing coaxially arranged with the fixing component and the spraying head housing and the fixing component rotatably connected with each other, the spraying head housing at least covering a front end of the fixing component, a plurality of spray nozzles arranged on a housing wall of the spraying head housing opposite to the front end of the fixing component, each of the spray nozzle arranged at intervals along a circumferential direction of the first flow passage, and when the spraying head housing rotates relative to the fixing component, each spray nozzle being alternately communicated with the second flow passage.

9. The spray gun according to claim 8, wherein, the gun head assembly further comprises:
a floating plate, the floating plate located between the front end of the fixing component and an inner wall of the spraying head housing, the floating plate movably arranged along an axial direction of the fixing component, and a through hole arranged on the floating plate at a position corresponding to the second flow passage; and
a first elastic unit, the first elastic unit configured to enable an elastic force to act forward on the floating plate so as to keep the floating plate in a state of abutting against the inner wall of the spraying head housing.

10. The spray gun according to claim 9, wherein, a first sealing ring is arranged between each of the spray nozzles and the floating plate, a protruding ring protruding toward the second flow passage is arranged at a position on the floating plate corresponding to the through hole, the protruding ring is inserted into the second flow passage and fits against an inner wall of the second flow passage, a sinking groove is arranged at a front end of the second flow passage, the protruding ring is inserted into the sinking groove, a gasket is arranged between the protruding ring and the sinking groove, a second sealing ring is arranged between the protruding ring and the gasket, the first elastic unit is a compression spring, the compression spring is installed in the second flow passage, and a front end of the compression spring abuts against the gasket.

11. The spray gun according to claim 10, wherein, the spraying head housing further comprises a cylindrical part covering a side surface of the fixing component, a third sealing ring is arranged between an inner wall of the cylindrical part and the side surface of the fixing component, an annular groove is arranged on the side of the fixing component, a limiting ring is arranged in the annular groove, the limiting ring is rotatably matched with the fixing component relatively, the spraying head housing is relatively fixedly connected with the limiting ring in a detachable manner, a limiting unit is arranged between the limiting ring and the fixing component, and the limiting unit is configured to keep the spraying head housing in a state that any of the spray nozzles on the spraying head housing is communicated with the second flow passage, and to release the spraying head housing when the spraying head housing is subjected to a torque greater than a preset value.

12. The spray gun according to claim 11, wherein, the limiting unit comprises a limiting block movably arranged along a radial direction of the fixing component, at least an outer end of the limiting block has a smooth outer contour, a second elastic unit is arranged between the limiting block and the fixing component, the second elastic unit is configured so that an elastic force acting on the limiting block is capable of driving the limiting block to move outward along the radial direction of the fixing component, a first limiting groove matched with the limiting block is arranged on an inner wall of the limiting ring, there is a plurality of the first limiting grooves, each of the first limiting grooves is arranged at intervals along a circumferential direction of the limiting ring, the limiting ring comprises two half rings, the cylindrical part is threaded with the limiting ring, a locking block is arranged on the inner wall of the cylindrical part, a locking groove is arranged on an edge of the limiting ring, the locking groove is formed between two cantilevers, a first one of the cantilevers is fixedly connected with the limiting ring, and a second one of the cantilever is elastically connected with the limiting ring, and the second cantilever is configured so that the locking block is capable of pushing the cantilever away to fall into the locking groove during a process of a threaded connection between the cylindrical part and the limiting ring, and the cantilever is capable of preventing the locking block from moving out of the locking groove.

13. The spray gun according to claim 1, further comprising a spraying rod assembly, wherein, the spraying rod assembly comprises:
a gun barrel,
a gun head assembly, the gun head assembly located at a front end of the gun barrel, and coaxially arranged with the gun barrel, a plurality of spray nozzles arranged at a front end of the gun head assembly, the spray nozzles arranged at intervals along a circumferential direction of the gun head assembly, a flow passage arranged in the gun head assembly, the flow passage communicated with the gun barrel, the gun head assembly comprising an adjustment device, and the adjustment device configured to enable each spray nozzle to be alternately communicated with the flow passage, and
an outer housing, as a surface decoration component of the gun barrel, and detachably installed on an outer side of the gun barrel.

14. The spray gun according to claim 1, wherein, the gun body comprises:
a gun body assembly, the gun body assembly comprising a first connecting part; and
a gun head assembly, the gun head assembly comprising a second connecting part; wherein
the gun body assembly is detachably connected with the gun head assembly through the first connecting part and the second connecting part;
the second connecting part is plug-in fitted with the first connecting part;
the first connecting part comprises a first limiting part and a first tube,
the second connecting part comprises a second limiting part and a gun barrel;
when the first connecting part and the second connecting part are plugged into a preset position, the second limiting part is capable of forming a limiting match with the first connecting part, to keep the first connecting part and the second connecting part in the preset position; and
the spray gun further comprises an elastic element, the elastic element is configured to apply an elastic force to the first connecting part and the second connecting part so as to cause the first connecting part and the second connecting part to be separated from each other when the first connecting part and the second connecting part are plugged into the preset position.

15. The spray gun according to claim 14, wherein, the connecting device further comprises a floating ring, the floating ring is movably connected with the first connecting part, a moving direction of the floating ring is parallel to a plug-in direction of the first connecting part and the second connecting part, the first connecting part has an annular housing wall, an outer wall of the floating ring is in contact with an inner wall of the annular housing wall, the elastic element acts on the floating ring, when the first connecting part and the second connecting part are plugged into the preset position, the elastic force of the elastic element is capable of driving an end face of the floating ring to contact an end face of the second connecting part, the first connecting part comprises the first tube, the second connecting part comprises the gun barrel, when the first connecting part and the second connecting part are plugged into the preset position, the first tube is fluidically communicated with the gun barrel, the second connecting part comprises an outer housing covering an outside of the gun barrel, a side wall of the outer housing close to one end of the first connecting part is flush with the outer wall of the floating ring, and when the first connecting part and the second connecting part are plugged into the preset position, the end face of the floating ring contacts an end face of the outer housing.

16. The spray gun according to claim 15, wherein, the first limiting part comprises a limiting hole with a non-circular cross-section, the second limiting part comprises an inserting rod, and a limiting head arranged at an end part of the inserting rod and matched with a contour of the cross-section of the limiting hole, a third notch is arranged on a hole wall of the limiting hole, when the first connecting part and the second connecting part are plugged into the preset position, the limiting head is aligned with the third notch, at this time, the limiting head is rotated to enable a contour of a cross-section of the limiting head to be misaligned with the contour of the cross-section of the limiting hole, so as to block the limiting head in the third notch, the first connecting part comprises a casing, a clamping hood and a core body, the casing is provided with a cylindrical part, the clamping hood is sleeved on an outer side of the cylindrical part, the core body is detachably installed in the cylindrical part, the first limiting part is formed on the core body, the floating ring is located between the core body and the casing and/or the clamping hood, a first protruding block is arranged on an outer wall of the core body, the elastic element is a compression spring, a first end of the compression spring abuts against the first protruding block, and a second end of the compression spring abuts against the floating ring.

17. The spray gun according to claim 13, further comprising an auxiliary agent container, wherein, the auxiliary agent container is installed on the outer housing through an auxiliary agent container mounting structure, and the auxiliary agent container mounting structure comprises:
a first port, the first port formed on an outer side of the gun head assembly of the spray gun, communicated with the flow passage in the gun head assembly, and arranged toward a front end or a rear end of the gun head assembly;
a second port, the second port formed on an outer side of the auxiliary agent container and communicated with a liquid storage space inside the auxiliary agent container;
a first connecting part, the first connecting part formed on an outer wall of the gun head assembly; and
a second connecting part, the second connecting part formed on an outer wall of the auxiliary agent container;
wherein, the first connecting part and the second connecting part are configured such that when the auxiliary agent container moves along a front-rear direction of the gun head assembly to connect the first port with the second port, the first connecting part and the second connecting part are capable of being clamped with each other to fix the auxiliary agent container to the outer wall of the gun head assembly.

18. The spray gun according to claim 17, wherein, one of the first connecting part and the second connecting part comprises a sliding block, and the other one of the first connecting part and the second connecting part comprises a sliding groove, wings are arranged on two sides of the sliding block and protrude perpendicularly to a length direction of the gun head assembly, a strip groove matching the wings is arranged on a side wall of the sliding groove, a first notch is arranged at a notch port of the sliding groove, the first notch penetrates from the notch port of the sliding groove to the strip groove, so as to insert the wing into the strip groove through the first notch, a first restrict part is arranged on the wing or the sliding block, a second restrict part is arranged on an inner wall of the sliding groove or the strip groove, one of the first restrict part and the second restrict part is a first protruding part with a smooth surface, the other one of the first restrict part and the second restrict part is a first concave part, when the first port is connected with the second port, the first protruding part is clamped with the first concave part, an inner end of the second port is provided with a pipette extending to an inside of the auxiliary agent container, a fourth sealing ring is arranged between the first port and the second port, the gun head assembly comprises a gun barrel and an outer housing, the outer housing is installed on an outer side of the gun barrel, a right-angle tube is connected with the gun barrel, a first end of the right-angle tube is communicated with the gun barrel, and a second end of the right-angle tube passes through an outer side of the outer housing to form the first port.

19. The spray gun according to claim 17, wherein, the auxiliary agent container comprises a container body and a side cover, a bottle mouth is formed on the container body, the side cover is detachably installed on the bottle mouth, the second port is located on the side cover, a fifth sealing ring is arranged between the container body and the side cover, a second protruding block is arranged on an outer wall of the bottle mouth, an arc groove matched with the second protruding block is arranged on an inner wall of the side cover, a second notch is arranged at an end part of the side cover, the second notch penetrates into the arc groove to enable the second protruding block to be inserted into the arc groove through the second notch, a second protruding part with a smooth surface is arranged on one of an inner wall of the arc groove and the second protruding block, a second concave part is arranged on the other one of the inner wall of the arc groove and the second protruding block, and when the second protruding block is inserted into the arc groove and rotated by a preset angle, the second protruding part is clamped with the second concave part.

20. The spray gun according to claim 1, wherein, the gun body assembly is formed with a handle part, a lower end of the handle part is fixedly connected with a battery pack compartment, the battery pack is installed in the battery pack compartment, the battery pack compartment comprises a body and a compartment cover, and the body is fixedly connected with the handle part,
the body is detachably connected with the compartment cover so as to enable the body and the compartment cover together to enclose a space to accommodate the battery pack;
at least one first magnetic unit is arranged at an edge of the body, at least one second magnetic unit is arranged at an edge of the compartment cover, and when the body is connected with the compartment cover, and the first magnetic unit and the second magnetic unit are attractable to each other, so as to enable the body and the bin cover to remain in a connected state;
one of the first magnetic unit and the second magnetic unit is a permanent magnet, and the other one of the first magnetic unit and the second magnetic unit is a ferromagnetic material or a permanent magnet.

21. The spray gun according to claim 20, wherein, a mounting groove to accommodate the first magnetic unit is arranged on an outer wall at the edge of the body, a fourth notch is formed on a side of the mounting groove close to the edge of the body, the second magnetic unit is arranged to protrude from the edge of the compartment cover, so as to enable the second magnetic unit to pass through the fourth notch and engage with the first magnetic unit in the mounting groove when the body is connected with the compartment cover, an inserting groove is arranged at the edge of the compartment cover, the second magnetic unit is inserted into the inserting groove, a limiting device is arranged between the second magnetic unit and the inserting groove, the limiting device is configured to enable the second magnetic unit to remain in the inserting groove, the limiting device comprises a wedge block protruding from an inner wall of the inserting groove and a second limiting groove arranged on the second magnetic unit, when the second magnetic unit is inserted into the inserting groove, the wedge block is clamped with the second limiting groove, a volume of the body is smaller than a volume of the battery pack, so as to enable at least a part of an area of the battery pack to protrude to an outer side of the body when the battery pack is inserted into the body, and the area protruding to the outer side of the body is accommodated in the compartment cover.

22. The spray gun according to claim 20, wherein, a third restrict part is arranged at the edge of the body, and a fourth restrict part is arranged at the edge of the compartment cover, the third restrict part and the fourth restrict part are configured to limit a relative movement direction of the body and the compartment cover to a first direction in a process of connecting the compartment cover to the body or separating the compartment cover from the body, the first direction is parallel to a direction of an attraction force between the first magnetic unit and the second magnetic unit, one of the third restrict part and the fourth limiting part is a second protruding flange, and the other one of the third restrict part and the fourth restrict part is a sinking groove that forms a plug-in fit with the second protruding flange, a wiring terminal is arranged at one end of an interior of the body away from the compartment cover, an elastic buckle is formed on a side wall of the body, and the elastic buckle is used to be clamped with a clamping groove arranged on a side wall of the battery pack.

23. A control method of a spray gun, applied to the spray gun, wherein, the spray gun comprises a display screen, a light module, a control switch, a fluid driving element, a battery pack, and a control module, the display screen, the light module, the control switch, the fluid driving element, and the battery pack are electrically connected with the control module respectively;
the control method comprises:
obtaining power information of the battery pack and state information of the control switch;
determining a display state of the display screen, a lighting mode of the light module and operating parameters of the fluid driving element according to the power information of the battery pack, the state information of the control switch, and preset control rules; and
controlling the display screen, the light module and the fluid driving element to work respectively according to the display state of the display screen, the lighting mode of the light module and the operating parameters of the fluid driving element.

24. The control method of the spray gun according to claim 23, wherein, the control switch comprises an on-off switch, and determining the display state of the display screen, the lighting mode of the light module, and the operating parameters of the fluid driving element according to the power information of the battery pack, the state information of the control switch, and the preset control rules comprises:
when the on-off switch is turned on and power of the battery pack is higher than a preset power, lighting the light module in a first mode, and the fluid driving element working in a standard state;
wherein, the control method further comprises:
obtaining fault information of the spray gun in real time; and
sending the fault information to the display screen to display;
before obtaining power information of the battery pack and state information of the control switch, the control method comprises:
obtaining access information of the battery pack;
when the battery pack is access, lighting the display screen and/or the light module in a third preset time, if the state information of the control switch does not change within the third preset time, turning off the display screen and/or the light module.

25. The control method of the spray gun according to claim 24, wherein, the control switch further comprises a speed regulation switch, and determining the display state of the display screen, the lighting mode of the light module, and the operating parameters of the fluid driving element according to the power information of the battery pack, the state information of the control switch, and the preset control rules further comprises:
when the on-off switch is turned on, the speed regulation switch is turned on and the power of the battery pack is higher than a preset power, lighting the light module in a second mode, and the fluid driving element working in a strong state;
wherein, determining a display state of the display screen, a lighting mode of the light module and operating parameters of the fluid driving element according to the power information of the battery pack, the state information of the control switch, and preset control rules further comprises:
when the on-off switch is turned on, the power of the battery pack is higher than the preset power and the speed regulation switch is turned on by clicking, the fluid driving element switching back to the standard state after the fluid driving element works in the strong state for the first preset time; and
when the on-off switch is turned on, the power of the battery pack is higher than the preset power and the speed regulation switch is in a pressed state, the fluid driving element keeping in the strong state to work.

26. The control method of the spray gun according to claim 24, wherein, determining the display state of the display screen, the lighting mode of the light module, and the operating parameters of the fluid driving element according to the power information of the battery pack, the state information of the control switch, and the preset control rules further comprises:
when the on-off switch is turned on and power of the battery pack is lower than the preset power, lighting the light module in a third mode;
wherein, the light module comprises an atmosphere light, determining a display state of the display screen, a lighting mode of the light module and operating parameters of the fluid driving element according to the power information of the battery pack, the state information of the control switch, and preset control rules further comprises:
when the on-off switch is turned off, turning off the atmosphere light;
wherein, the light module comprises an annular light, determining a display state of the display screen, a lighting mode of the light module and operating parameters of the fluid driving element according to the power information of the battery pack, the state information of the control switch, and preset control rules further comprises:
when the on-off switch is turned off and the power of the battery pack is higher than the preset power, lighting the annular module in a fourth mode;
wherein, determining a display state of the display screen, a lighting mode of the light module and operating parameters of the fluid driving element according to the power information of the battery pack, the state information of the control switch, and preset control rules further comprises:
when the on-off switch is turned on, the display screen displaying the power information of the battery pack in real time; and
when the on-off switch is turned off, turning off the display screen after a second preset time.

27. A spray gun, comprising a display screen, a light module, a control switch, a fluid driving element, a battery pack, and a control module, wherein, the display screen, the light module, the control switch, the fluid driving element, and the battery pack are electrically connected with the control module respectively;
and the control module comprises:
an information acquisition module, the information acquisition module configured to obtain power information of the battery pack and state information of the control switch;
an operation module, the operation module configured to determine a display state of the display screen, a lighting mode of the light module and operating parameters of the fluid driving element according to the power information of the battery pack, the state information of the control switch, and preset control rules; and
an execution module, the execution module configured to control the display screen, the light module and the fluid driving element to work respectively according to the display state of the display screen, the lighting mode of the light module and the operating parameters of the fluid driving element.
